(19) United States
(12) Patent Application Publication
(10) Pub. No.: US 2026/0093176 A1
(43) Pub. Date: Apr. 2, 2026

(54) ELECTROACTIVE COMPOUNDS, COMPOSITIONS INCLUDING THE SAME, AND PATTERN FORMATION METHODS

(71) Applicant: DuPont Electronic Materials International, LLC, Marlborough, MA (US)

(72) Inventors: Mingqi Li, Shrewsbury, MA (US); Emad Aqad, Northborough, MA (US); Kenneth Hernandez, Ashland, MA (US); Doris Kang, Shrewsbury, MA (US); Li Cui, Westborough, MA (US); Sheng Liu, Bow, NH (US); Peter Trefonas, III, Medway, MA (US)

(21) Appl. No.: 19/332,356

(22) Filed: Sep. 18, 2025

Related U.S. Application Data
(60) Provisional application No. 63/699,950, filed on Sep. 27, 2024.

(51) Int. Cl. G03F 7/039; G03F 7/004; G03F 7/16; G03F 7/20; G03F 7/38

(52) U.S. Cl. CPC G03F 7/0392; G03F 7/0045; G03F 7/168; G03F 7/2004; G03F 7/2059; G03F 7/38

(57) ABSTRACT

A composition including an acid-sensitive polymer comprising a first repeating unit derived from a monomer comprising an acid-decomposable group; a photoacid generator compound; a non-polymeric electron acceptor compound that has a greater electron affinity than an electron affinity of the photoacid generator compound, wherein the non-polymeric electron acceptor compound does not generate a photoacid, and wherein the non-polymeric electron acceptor compound does not comprise a plurality of diazonaphthoquinone (DNQ) groups; and a solvent, wherein the solvent is present in the composition in an amount greater than 50 weight percent, based on total weight of the composition, wherein the composition is a positive-acting EUV photoresist or an electron beam resist.

### CROSS-REFERENCE TO RELATED APPLICATIONS

This application claims priority to and all benefits of U.S. Provisional Patent Application Ser. No. 63/699,950, filed on Sep. 27, 2024, the entire content of which is incorporated herein by reference.

### FIELD

The present invention relates to electroactive compounds for compositions, including photoresist compositions, and to pattern formation methods using such compositions. The invention finds applicability in lithographic applications in the semiconductor manufacturing industry.

### BACKGROUND

Photoresist materials are photosensitive compositions typically used for transferring an image to one or more underlying layers such as a metal, semiconductor or dielectric layer disposed on a semiconductor substrate. To increase the integration density of semiconductor devices and allow for the formation of structures having dimensions in the nanometer range, photoresists and photolithography processing tools having high-resolution capabilities have been and continue to be developed.

Chemically amplified photoresists are conventionally used for high-resolution processing. Such resists typically employ a polymer having acid-labile groups, a photoacid generator and an acid quenching material. Pattern-wise exposure to activating radiation through a photomask causes the acid generator to form an acid which, during post-exposure baking, causes cleavage of the acid-labile groups in exposed regions of the polymer. Acid quenching materials are often added to the photoresist composition for controlling the diffusion of the acid to unexposed region to improve the contrast. The result of the lithographic process is the creation of difference in solubility characteristics between exposed and unexposed regions of the resist in a developer solution. In a positive tone development (PTD) process, exposed regions of the photoresist layer become soluble in the developer and are removed from the substrate surface, whereas unexposed regions, which are insoluble in the developer, remain after development to form a positive image. The resulting relief image permits selective processing of the substrate.

Extreme ultraviolet lithography (EUVL) is an optical lithography technology that can image the most critical small feature patterns for advanced integrated circuits. The semiconductor industry has adapted EUVL as the patterning technology of choice for printing critical features on 7 nm and smaller node devices in contact, via, metal line and cut layers, for example where the cuts can be applied to FinFET, nanosheet FET, or metal lines. Single exposure EUV enables chipmakers to pattern the most challenging features at 5 nm nodes. The significant improvement in EUV technology in the past few years allows for acceptable throughput using, e.g., ASML's EUV NXE:3400C scanner, which incorporates 0.33 numerical aperture (NA) lens. Extension of 0.33 NA EUV single exposure patterning to the 3 nm node and beyond requires continuous advancement in photoresist technology. Essential to the continuation of advanced patterning techniques is the development of lithographic patterning solutions to support High-NA EUV. As the industry looks forward to the implementation of High NA (0.55 NA) EUV, the demand for new materials is heightened even further. These essential materials include photoresist, underlayer and rinse materials that will help the industry surpass the current requirement for Resolution, Line Width Roughness, and Sensitivity in modern photoresists while meeting the targets for stochastic and non-stochastic defectivity as well as etch pattern transfer. The requirement for balancing these properties is industry wide challenge. It is essential to develop new chemistry, new formulation strategy, as well as their fundamental understanding to break this tradeoff to extend Moore's law into the future generations of devices.

### SUMMARY

An aspect provides a composition including an acid-sensitive polymer comprising a first repeating unit derived from a monomer comprising an acid-decomposable group; a photoacid generator compound; a non-polymeric electron acceptor compound that has a greater electron affinity than an electron affinity of the photoacid generator compound, wherein the non-polymeric electron acceptor compound does not generate a photoacid, and wherein the non-polymeric electron acceptor compound does not comprise a plurality of diazonaphthoquinone (DNQ) groups; and a solvent, wherein the solvent is present in the composition in an amount greater than 50 weight percent, based on total weight of the composition, wherein the composition is a positive-acting EUV photoresist or an electron beam resist.

Another aspect provides a pattern forming method including (a) applying a layer of the composition on a substrate; soft-baking the composition layer; exposing the soft-baked composition layer to EUV or electron beam activating radiation; post-exposure baking the composition layer; and developing the post-exposure baked composition layer to provide a resist relief image.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. The modifier “about” used in connection with a quantity is inclusive of the stated value and has the meaning dictated by the context (e.g., includes the degree of error associated with measurement of the particular quantity). All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another. When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “actinic rays” or “radiation” means, for example, a bright line spectrum of a mercury lamp, far ultraviolet rays represented by an excimer laser, extreme ultraviolet rays (EUV light), X-rays, particle rays such as electron beams and ion beams, or the like. In addition, in the present invention, “light” means actinic rays or radiation. The krypton fluoride laser (KrF laser) is a particular type of excimer laser, which is sometimes referred to as an exciplex laser. “Excimer” is short for “excited dimer,” while “exciplex” is short for “excited complex.” An excimer laser uses a mixture of a noble gas (argon, krypton, or xenon) and a halogen gas (fluorine or chlorine), which under suitable conditions of electrical stimulation and high pressure, emits coherent stimulated radiation (laser light) in the ultraviolet range. Furthermore, “exposure” in the present specification includes, unless otherwise specified, not only exposure by a mercury lamp, far ultraviolet rays represented by an excimer laser, X-rays, extreme ultraviolet rays (EUV light), or the like, but also writing by particle rays such as electron beams and ion beams.

A used herein, an “organic group” includes one or more carbon atoms, for example 1 to 60 carbon atoms. The term “hydrocarbon” refers to an organic compound or to an organic group having at least one carbon atom and at least one hydrogen atom. The term “alkyl” refers to a straight or branched chain saturated hydrocarbon group having the specified number of carbon atoms and having a valence of one; “alkylene” refers to an alkyl group having a valence of two; “hydroxyalkyl” refers to an alkyl group substituted with at least one hydroxyl group (—OH); “alkoxy” refers to “alkyl-O—”; “carboxyl” and “carboxylic acid group” refer to a group having the formula “—C(═O)—OH”; “cycloalkyl” refers to a monovalent group having one or more saturated rings in which all ring members are carbon; “cycloalkylene” refers to a cycloalkyl group having a valence of two; “alkenyl” refers to a straight or branched chain, monovalent hydrocarbon group having at least one carbon-carbon double bond; “alkenoxy” refers to “alkenyl-O—”; “alkenylene” refers to an alkenyl group having a valence of two; “cycloalkenyl” refers to a non-aromatic cyclic divalent hydrocarbon group having at least three carbon atoms, with at least one carbon-carbon double bond; “alkynyl” refers to a monovalent hydrocarbon group having at least one carbon-carbon triple bond; the term “aromatic group” refers to a monocyclic or polycyclic ring system that satisfies the Huckel Rule and includes carbon atoms in the ring, and optionally may include one or more heteroatoms selected from N, O, and S instead of a carbon atom in the ring; “aryl” refers to a monovalent aromatic monocyclic or polycyclic ring system where every ring member is carbon, and may include a group with an aromatic ring fused to at least one cycloalkyl or heterocycloalkyl ring; “arylene” refers to an aryl group having a valence of two; “alkylaryl” refers to an aryl group that has been substituted with an alkyl group; “arylalkyl” refers to an alkyl group that has been substituted with an aryl group; “aryloxy” refers to “aryl-O—”; and “arylthio” refers to “aryl-S—”.

The prefix “hetero” means that the compound or group includes at least one member that is a heteroatom (e.g., 1, 2, 3, or 4 or more heteroatom(s)) instead of a carbon atom, wherein the heteroatom(s) is each independently N, O, S, Si, or P; “heteroatom-containing group” refers to a substituent group that includes at least one heteroatom; “heteroalkyl group” refers to an alkyl group having 1-4 or more heteroatoms instead of carbon; “heterocycloalkyl group” refers to a cycloalkyl group having 1-4 or more heteroatoms as ring members instead of carbon; “heterocycloalkylene group” refers to a heterocycloalkyl group having a valence of two; “heteroaryl group” refers to an aryl group having 1-4 or more heteroatoms as ring members instead of carbon; and “heteroarylene group” refers to an heteroaryl group having a valence of two.

Each of the foregoing substituent groups optionally may be substituted unless expressly provided otherwise. For example, where the group is cited without specifying that it is substituted or unsubstituted, the group includes both a group having no substituent and a group having a substituent. The term “optionally substituted” refers to being substituted or unsubstituted.

“Substituted” means that at least one hydrogen atom of the chemical structure is replaced with another terminal substituent group that is typically monovalent, provided that the designated atom's normal valence is not exceeded. When the substituent is oxo (i.e., ═O), then two geminal hydrogen atoms on the carbon atom are replaced with the terminal oxo group. Combinations of substituents or variables are permissible. Exemplary substituent groups that may be present on a “substituted” position include, but are not limited to, nitro (—NO₂), cyano (—CN), hydroxyl (—OH), oxo (=O), amino (—NH₂), mono- or di-(C₁₋₆)alkylamino, alkanoyl (such as a C₂₋₆ alkanoyl group such as acyl), formyl (—C(═O)H), carboxylic acid or an alkali metal or ammonium salt thereof; esters (including acrylates, methacrylates, and lactones) such as C₂₋₆ alkyl esters (—C(═O)O-alkyl or —OC(═O)-alkyl) and C₇₋₁₃ aryl esters (—C(═O)O-aryl or —OC(═O)-aryl), amido (—C(═O)NR₂ wherein R is hydrogen or C₁₋₆ alkyl), carboxamido (—CH₂C(═O)NR₂ wherein R is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₂₋₁₈ heterocycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₃₋₁₂ heterocycloalkyl, C₃₋₁₂ heteroaryl, C₁₋₆ alkyl sulfonyl (—S(═O)₂-alkyl), C₆₋₁₂ arylsulfonyl (—S(═O)₂-aryl), or tosyl (CH₃C₆H₄SO₂—).

The term “halogen” means a monovalent substituent that is fluorine (fluoro), chlorine (chloro), bromine (bromo), or iodine (iodo). The prefix “halo” means a group including one or more of a fluoro, chloro, bromo, or iodo substituent instead of a hydrogen atom. A combination of halo groups (e.g., bromo and fluoro), or only fluoro groups may be present. For example, the term “haloalkyl” refers to an alkyl group substituted with one or more halogens. As used herein, “substituted C₁₋₈ haloalkyl” refers to a C₁₋₈ alkyl group substituted with at least one halogen, and is further substituted with one or more other substituent groups that are not halogens.

As used herein, an “acid-labile group” refers to a group in which a bond is cleaved by the action of an acid, optionally and typically with thermal treatment, resulting in formation of a polar group, such as a carboxylic acid or alcohol group, being formed on the polymer, and optionally and typically with a moiety connected to the cleaved bond becoming disconnected from the polymer. As used herein, the term “acid-decomposable group” is synonymous with an acid-labile groups. In other systems, a non-polymeric compound may include an acid-labile group that may be cleaved by the action of an acid, resulting in formation of a polar group, such as a carboxylic acid or alcohol group on a cleaved portion of the non-polymeric compound. Such acid is typically a photo-generated acid with bond cleavage occurring during post-exposure baking (PEB); however, embodiments are not limited thereto, and, for example, such acid may be thermally generated. Suitable acid-labile groups include, for example: tertiary alkyl ester groups, secondary or tertiary aryl ester groups, secondary or tertiary ester groups having a combination of alkyl and aryl groups, tertiary alkoxy groups, tertiary carbonate groups, acetal groups, or ketal groups. Acid-labile groups are also commonly referred to in the art as “acid-cleavable groups,” “acid-cleavable protecting groups,” “acid-labile protecting groups,” “acid-leaving groups,” “acid-decomposable groups,” and “acid-sensitive groups.”

As used herein, when a definition is not otherwise provided, a “divalent linking group” refers to a divalent group including one or more of —O—, —S—, —Te—, —Se—, —C(O)—, —C(O)O—, —N(R^{a})—, —S(O)—, —S(O)₂—, —C(S)—, —C(Te)—, —C(Se)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R^{a} is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. Typically, the divalent linking group includes one or more of —O—, —S—, —C(O)—, —C(O)O—, —N(R^{a})—, —S(O)—, —S(O)₂—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R^{a} is hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. More typically, the divalent linking group includes at least one of —O—, —C(O)—, —C(O)O—, —N(R^{a})—, —C(O)N(R^{a})—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R^{a} is hydrogen, deuterium, substituted or unsubstituted C₁₋₁₀ alkyl, substituted or unsubstituted C₁₋₁₀ heteroalkyl, substituted or unsubstituted C₆₋₁₀ aryl, or substituted or unsubstituted C₃₋₁₀ heteroaryl.

As described above, chemical amplified photoresists have been the workhouse for semiconductor high resolution patterning for many years. The method uses a photoacid generated through radiation exposure to deprotect a leaving group on a polymer chain and to regenerate itself for further deprotection of other leaving groups in many cycles. This generates solubility switching between exposed areas versus unexposed areas of the substrate coating layers. Traditionally, chemically amplified photoresists work based on principles of acid diffusion to dramatically increase resist sensitivity. Deep UV photoresist products, as well as low NA EUV photoresists, still use chemically amplified photoresist based chemistry. Controlling the photoacid diffusion length can be important for performance, as extensive acid diffusion may lead to blur and deteriorate the roughness and resolution of the resulting images and patterns.

EUV patterning brings additional challenges based on its unique photochemical mechanism. During EUV exposure, when a 92-eV photon (13.5 nm) is first absorbed by the photoresist composition, it mostly leads to the ionization of the polymer matrix, and subsequently generates a primary electron. The primary electron is highly energetic, and can further excite the matrix to generate further secondary electrons, including thermalized low energy secondary electrons. Thermalized lower energy secondary electrons essentially react with the photoacid generator (PAG) components in an irreversible manner, which results in PAG decomposition and the release of photoacid. Thus, to improve the EUV resist sensitivity, the PAG component may be selected with a higher electron affinity (or, a higher reduction potential) to favor the addition of secondary electrons. In addition, the high energy of EUV radiation implies a scarce number of EUV photons at typical resist exposure dose. Therefore, high EUV absorbance cross section of the photoresist composition is a useful element in resist design and component selections.

In an EUV chemically amplified photoresist, there exist additional challenges associated with involvement of the secondary electron in the acid generation pathway. Electron blur may be significant, since electron thermalization distance (meaning the total distance an electron travels in a random-walk model, after it is generated and before being quenched or reacts with PAG) in a EUV resist is measured to be an average 3-7 nm in an organic polymeric matrix. It can also be denoted as secondary electron diffusion, meaning the scattering and movement of secondary electrons generated when an EUV photon interacts with a resist material, which significantly impacts the precision of the final pattern due to their ability to spread beyond the intended exposure area, causing blurring at the edges of features. Increasing resist film density, such as in metal oxide resists, can be beneficial in suppressing secondary electron blur. However, lower density films made from organic chemically amplified photoresist materials are believed to possess higher electron blur, which can match the level of roughness required for EUV patterning of high-resolution features.

The present invention addresses the electron blur challenge by providing electron blur control additives. These additives are non-polymeric electron acceptor compounds that are used in EUV photoresist or E-beam compositions (including organic, inorganic, metal resists, or the like). Using the electron acceptor compounds controls the electron blur stochastics, which essentially improves the printed feature resolution and roughness. In a chemical amplified EUV photoresist or E-beam resist, the disclosed non-polymeric electron acceptor compound additives have higher electron affinity (or higher reduction potential) than the electron affinity of the photoacid generator compound(s) that is present, thus they may quench the secondary electron more preferentially before it reacts with the PAG compound, to effectively improve the deprotection contrast and thus lithographic performance.

Without being limited to theory, the mechanism of the secondary electron acceptor or quencher is by mimicking the photoacid diffusion control of a basic quencher additive in a traditional chemically amplified photoresist system for deep UV lithography. Conceptually, introducing a secondary electron quencher component in the formulation to annihilate the fast-diffusing electrons could inherently control the electron blur, thus improving the contrast and thus ultimately improving resolution and roughness.

As used herein, “reduction potential” represents the affinity of a material to accept an electron(s). It can be measured by cyclic voltammetry, by measuring the Formal Potential (E^{o′}). Using the cyclic voltammetry of an acceptor compound, the reduction potential value is estimated by the cathodic peak potentials. In a typical cyclic voltammetry measurement, each of the material is dissolved in distilled and dried solvent such as dry acetonitrile to prepare a 1 millimolar (mM) solution of the redox molecule for the measurement. An electrolyte solution, such as 0.1 M solution of tetrabutylammonium perchlorate is used as a supporting electrolyte. With respect to electrodes, a 4 mm Pt disk, coiled Pt wire, and a Ag/AgCl electrode can be used as a working electrode, a counter electrode, and a reference electrode, respectively. The solution is purged with N₂ gas for 5-10 minutes prior to the electrochemical measurement to displace dissolved O₂. The measurement is typically conducted at room temperature at a desired scanning rate.

As used herein, “electron affinity” represents the affinity of a material to accept electron(s). Electron affinity may be calculated by forming a specimen layer on a quartz substrate. Subsequently, an absorption spectrum of the prepared specimen may be measured using a spectrophotometer, and an optical band gap may be calculated from the result of the absorption edge of the obtained absorption spectrum. The electron affinity may be estimated by subtraction between the ionization potential obtained below and the calculated optical band gap.

Ionization potential can be measured as follows. A specimen was formed on a glass substrate provided with an ITO film. Subsequently, the number of photoelectrons was measured by using photoemission yield spectroscopy in air, where ultraviolet irradiation energy was changed, and the energy position when a photoelectron was detected for the first time was assumed to be the ionization potential.

Quantum chemical calculations were used in estimating key electronic properties of molecules used in the compositions described herein. These calculations utilize the laws of quantum mechanics to provide accurate predictions of the properties of molecules. The person having ordinary skill in the art can use quantum chemical calculations to obtain a detailed understanding of the electronic structure of a molecule and how this structure affects its overall properties. Quantum chemical calculations were used to calculate the lowest unoccupied molecular orbital (LUMO) energies. Density Functional Theory (DFT) calculations were used according to the Gaussian 16 software package at the B3LYP level, employing the 6-31+G(d,p) basis set. Using DFT, the geometry of the molecule was first optimized and confirmed. Typically, vibration frequency analysis was used to confirm minimum energy geometry. Once optimized, the DFT output file containing the molecular orbital energies was obtained.

Quantum chemical calculations may also be used to estimate the reduction potential of molecules. The computation method specified in J. Phys. Chem. C 2014, 118, 12, 6046-6051 is well suited for the calculation of the reduction potential of organic compounds. Using the computation method, density functional theory (DFT) calculations were performed to confirm global minimum energy structures. The modeling was performed for each molecule in solution by using the polarizable continuum (PC) model with a solvent, such as propylene carbonate. DFT calculations were used to calculate the energies before and after electron addition (reduction). These computed energies were then used to calculate the reduction reaction free energy ΔG. The formal potential, E, for the molecules was calculated from the free energy difference of the reactions ΔG, using ΔG=nFE where n is the number of electrons transferred and F is Faraday's constant. This calculation results in the E vs vacuum and was then converted to the reference of Ag/AgCl.

Quantum chemical calculations may also be used to estimate electron affinity of PAG cations and electron acceptor additive compounds. The electron affinity is defined as the energy released when an electron is added to a molecule. Typically, vibration frequency analysis was used to confirm global minimum energy geometry. The computed energies of the optimized structures were used to calculate the adiabatic electron affinity. In cases where geometry cannot be optimized, such as for unstable radicals, the vertical electron affinity was calculated. For neutral molecules, the electron affinity was computed as the energy difference between neutral form and the form produced upon the addition of one electron, which was the corresponding anion-radical form. For positively charged species, such as a sulfonium cation having a charge of +1, the vertical electron affinity was computed as the energy difference between the cation with +1 charge and the radical form that was produced upon the addition of one electron.

Herein, a material that donates an electron to another molecule or a chemical species during a chemical reaction is referred to as an electron-donor material, and a material that accepts an electron from another molecule or a chemical species during a chemical reaction is referred to as an electron-acceptor material. When two different types of organic materials are used, the type that serves as a donor material and the type that serves as an acceptor material are generally determined in accordance with the relative position of the energy levels of the highest-occupied-molecular-orbital (HOMO) and the lowest-unoccupied-molecular-orbital (LUMO) of each of the two types of organic materials at the contact interface. The energy difference between the vacuum level (0 eV) and the energy level of the LUMO correlates with electron affinity. Generally, the lower the LUMO energy level, the better the electron accepting ability. In addition, the energy difference between the vacuum level and the energy level of the HOMO correlates with ionization potential, the higher the HOMO energy the better the electron donating ability.

The present inventors have discovered that EUV or E-beam photoresist compositions have superior lithographic performance when an efficient non-polymeric secondary electron acceptor compound with a higher electron affinity than the photoacid generator compound is added to the composition. The inventors have discovered that “fast diffusing” secondary electrons that diffuse into the unexposed regions may be annihilated (or quenched) before they react with the PAG cation to generate photoacid for undesired resist leaving group deprotection. The material having a lower LUMO energy level, that is, having a higher electron affinity and reduction potential, serves as the electron acceptor material.

Provided herein is a composition that includes an acid-sensitive polymer that includes a first repeating unit derived from a monomer including an acid-decomposable group. The composition includes a photoacid generator compound. The composition includes a non-polymeric electron acceptor compound that has a greater electron affinity than an electron affinity of the photoacid generator compound, wherein the non-polymeric electron acceptor compound does not generate a photoacid, and wherein the non-polymeric electron acceptor compound does not comprise a plurality of diazonaphthoquinone (DNQ) groups. The composition also includes a solvent, wherein the solvent is present in the composition in an amount greater than 50 weight percent (wt %), based on total weight of the composition. The composition is a positive-acting EUV photoresist or an electron beam resist.

The non-polymeric electron acceptor compound has a greater electron affinity than an electron affinity of the photoacid acid generator (or, in the case of an ionic photoacid generator compound, a greater electron affinity than an electron affinity of the cation of the photoacid generator). In addition, the non-polymeric electron acceptor compound does not generate a photoacid upon exposure to EUV radiation or an electron beam, and the non-polymeric electron acceptor compound does not comprise a plurality of DNQ groups. The electron affinity of the PAG compound may be determined based on the structure of the PAG compound. For example, the non-polymeric electron acceptor compound may have a greater electron affinity than an electron affinity of the cation portion of the photoacid generator compound, or the non-polymeric electron acceptor compound may have a greater electron affinity than an electron affinity of the zwitterionic portion of the photoacid generator compound, or the non-polymeric electron acceptor compound may have a greater electron affinity than an electron affinity of the entire structure of a non-ionic photoacid generator compound. As used herein, the photoacid generator compound might have multiple active centers, such as multiple cations, that are electron reactive. The photoacid generator compound may be a small molecule compound or may be a polymer compound.

In some embodiments, the non-polymeric electron acceptor compound has a greater electron affinity than an electron affinity of triphenyl sulfonium, for example a substituted triphenyl sulfonium. In some embodiments, the non-polymeric electron acceptor compound has a greater electron affinity than an electron affinity of diphenyl iodonium, for example a substituted diphenyl iodonium.

The non-polymeric electron acceptor compound includes a conjugated organic group, and may be substituted through conjugation with one or more electron withdrawing groups. A conjugated organic compound or structure is a type of organic molecular structure in which there are alternating single and double bonds between carbon atoms and/or other atoms. In some embodiments, the non-polymeric electron acceptor compound includes an conjugated organic group and does not further include an electron withdrawing group. Exemplary conjugated organic groups include groups include vinyl, 1,3-butadienyl, ethynyl, carbonyl, 1,3-butadienyl, and combinations thereof. Other exemplary conjugated organic groups include aromatic and heteroaromatic groups, such as those that have five- or six-membered rings, or combinations thereof. Some examples of suitable groups include five or six-membered rings, or combinations of multiple rings, with or without heteroatoms. Another class of conjugated organic groups useful in the present invention are aromatic quinonoids, especially substituted or unsubstituted benzoquinones or naphthoquinones. The quinone may be an alkyl-, alkoxy-, hydroxy-, halo-, nitro-, or cyano-substituted benzoquinone or naphthoquinone or combinations thereof. Other examples of quinonoid groups includes dichloro, dicyano benzoquinone, cyanil, chloranil, bromonil, and tetracyanoquinodimethane. Other examples of conjugated organic groups include but not limited to groups derived from tetracyanoethylene, fluorenone, or fluorenone substituted with electron withdrawing groups such as, 2-nitrofluorenone, 2,7-dinitrofluorenone, 2,4,7 trinitrofluorenone, fullerene and derivatives thereof, porphyrin and derivatives thereof, phthalocyanine and derivatives thereof, and pyridinium salts, or the like. Exemplary electron withdrawing groups include, but are not limited to, cyano (including C(CN)₂ and N—CN), pyridinium, oxo, nitro, halogen, haloalkyl, an ester group, a sulfone group, a sulfonamide group, a sulfonimide group, a phthalimide group, and a naphthalimide group. Combinations of one or more different electron withdrawing groups may be used. In some embodiments, the conjugated organic group may include an electron withdrawing groups within the structure thereof. In some embodiments, the conjugated organic group may include a cationic atom, such as a nitrogen cation, which is considered to be an electron withdrawing group therein.

Still other examples of the non-polymeric electron acceptor compound include ammonium salts (substituted or unsubstituted) having a greater electron affinity than the electron affinity of the photoacid generator.

In some embodiments, the non-polymeric electron acceptor compound may include a compound represented by one or more of Formulae (1) to (5):

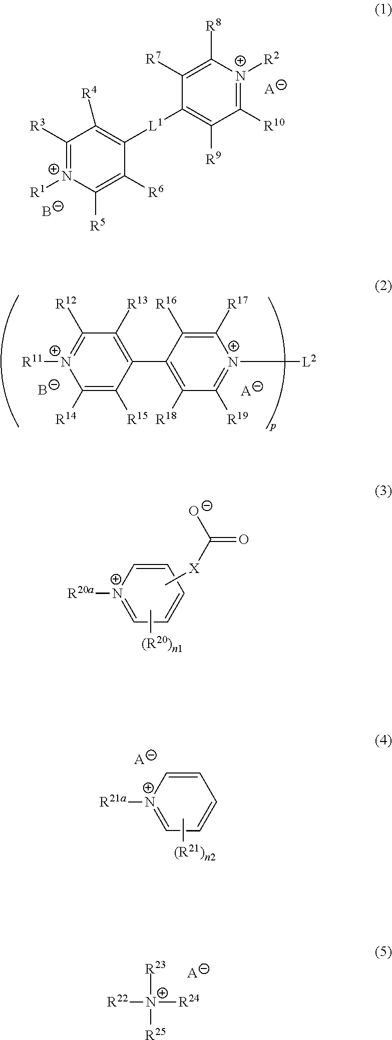

In Formulae (1) to (5), R¹ to R²⁵, R^{20a}, and R^{21a} are each independently hydrogen, deuterium, halogen, nitro, amino, cyano, pyridinium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl. In some embodiments, R¹ to R²⁵, R^{20a}, and R^{21a} may each independently be hydrogen, deuterium, C₁₋₄ alkyl, cyano, pyridinium, nitro, or C₁₋₄ fluoroalkyl. Typically, R¹ to R²⁵, R^{20a}, and R^{21a} are each independently hydrogen, substituted or unsubstituted C₁₋₄ alkyl, or substituted or unsubstituted C₁₋₄ fluoroalkyl.

In Formulae (1) to (5), each of R¹ to R²⁵, R^{20a}, and R^{21a} optionally further comprises one or more divalent linking groups as a part of its structure. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (1), adjacent two or more of R¹ to R¹⁰ optionally form a ring with each other via a divalent linking group, wherein each of the one or more divalent linking groups is substituted or unsubstituted, and wherein the ring is substituted or unsubstituted.

In Formula (1), L¹ is a single bond or a divalent linking group. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. For example, L¹ may be a single bond, substituted or unsubstituted C₆₋₃₀ arylene, or substituted or unsubstituted C₃₋₃₀ heteroarylene.

In Formula (2), adjacent two or more of R¹¹ to R¹⁹ optionally form a ring with each other via a divalent linking group, wherein each of the one or more divalent linking groups is substituted or unsubstituted, and wherein the ring is substituted or unsubstituted.

In Formula (2), L² is a single bond or a multivalent linking group. Exemplary multivalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. When the group is multivalent, then it has a valency of two or greater. For example, L² may be a single bond, substituted or unsubstituted multivalent C₆₋₃₀ arylene, or substituted or unsubstituted multivalent C₃₋₃₀ heteroarylene.

In Formula (2), p is an integer from 2 to 6. Typically, p is an integer from 2 to 4.

In Formulae (1) and (2), A⁻ and B⁻ are each independently an organic anion, wherein A⁻ and B⁻ are optionally joined together to form a divalent organic anion. Exemplary organic anions include those whose conjugated acid is typically a pKa from −15 to 10. For example, A⁻ and B⁻ may each independently be a sulfonate, a carboxylate, an anion of a sulfonamide, an anion of a sulfonimide, or a methide anion.

In Formula (3), adjacent two or more R²⁰ optionally form a ring with each other via a divalent linking group, wherein each of the one or more divalent linking groups is substituted or unsubstituted, and wherein the ring is substituted or unsubstituted.

In Formula (3), n1 is an integer from 0 to 4. Preferably, n1 is 0 or 1.

In Formula (3), X is a single bond or one or more divalent linking groups. Each of the one or more divalent linking groups may be substituted or unsubstituted. Exemplary divalent linking groups may each independently be selected from —O—, —C(O)—, —C(O)O—, —S—, —S(O)—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. Typically, X may be a single bond or substituted or unsubstituted C₁₋₂₀ alkylene, preferably a single bond or substituted or unsubstituted C₁₋₁₀ alkylene.

In Formula (4), A⁻ is an organic anion. Exemplary organic anions include those whose conjugated acid is typically a pKa from −15 to 10. For example, A⁻ may be a sulfonate, a carboxylate, an anion of a sulfonamide, an anion of a sulfonimide, or a methide anion.

In Formula (4), n2 is an integer from 0 to 5. Typically, n2 is 0 or 1.

In Formula (4), adjacent two or more R²¹ optionally form a ring with each other via a divalent linking group, wherein each of the one or more divalent linking groups is substituted or unsubstituted, and wherein the ring is substituted or unsubstituted.

In Formula (5), two or more of R²² to R²⁵ optionally form a ring with each other via a divalent linking group, wherein the divalent linking groups is substituted or unsubstituted, and wherein the ring is substituted or unsubstituted.

In Formula (5), A⁻ is an organic anion. Exemplary organic anions include those whose conjugated acid is typically a pKa from −15 to 10. For example, A⁻ may be a sulfonate, a carboxylate, an anion of a sulfonamide, an anion of a sulfonimide, or a methide anion.

In some embodiments, the non-polymeric electron acceptor compound may include one or more compounds of Formulae (6) to (26):

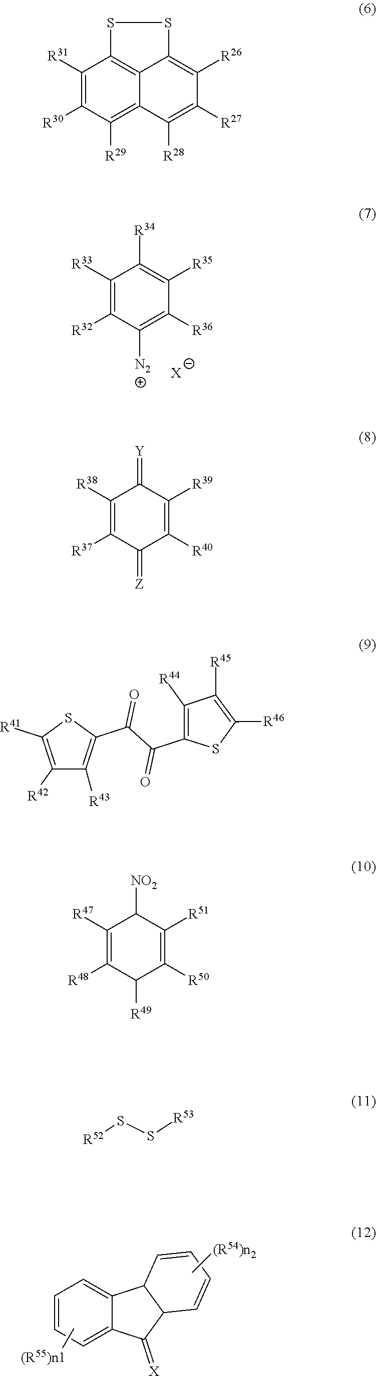

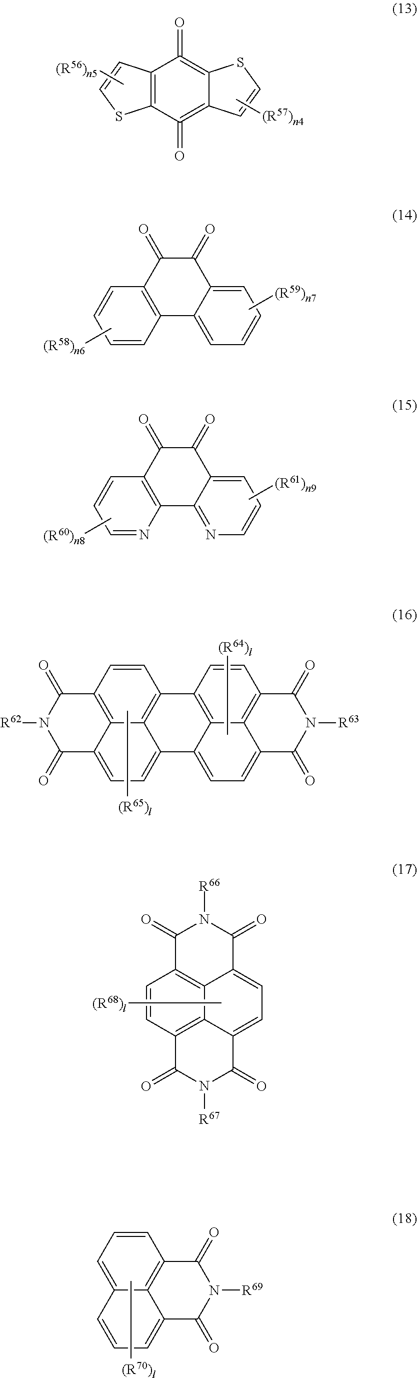

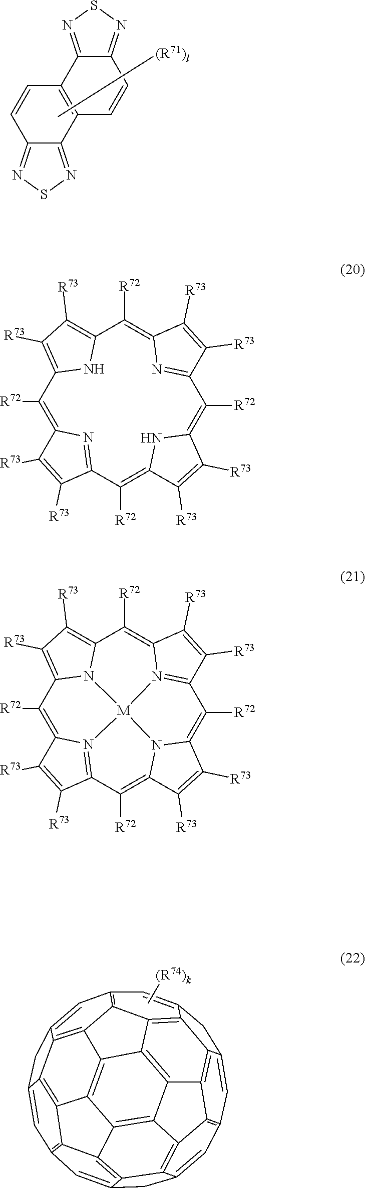

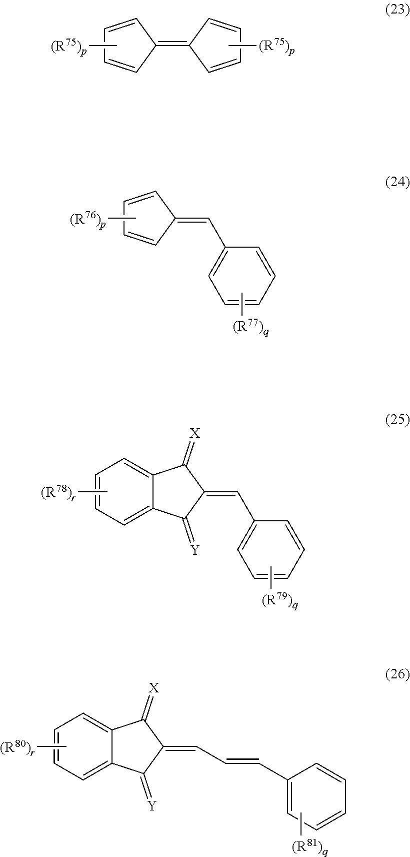

In Formulae (6) to (26), R²⁶ to R⁸¹ are each independently hydrogen, deuterium, halogen, nitro, amino, cyano, pyridinium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl. Typically, R²⁶ to R⁸¹ are each independently hydrogen, deuterium, halogen, substituted or unsubstituted C₁₋₂₀ alkyl, substituted or unsubstituted C₁₋₂₀ heteroalkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₂₋₂₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl.

In Formulae (6) to (26), each of R²⁶ to R⁸¹ optionally further comprises one or more divalent linking groups as a part of its structure. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (6), adjacent two or more of R²⁶ to R³¹ optionally form a ring with each other via one or more divalent linking groups, wherein each of the one or more divalent linking groups is substituted or unsubstituted, and wherein the ring is substituted or unsubstituted.

In Formula (7), adjacent two or more of R³² to R³⁶ optionally form a ring with each other via one or more divalent linking groups, wherein each of the one or more divalent linking groups is substituted or unsubstituted, and wherein the ring is substituted or unsubstituted.

In Formula (7), X⁻ is an organic anion. Exemplary organic anions include those whose conjugated acid is typically a pKa from −15 to 10. For example, X⁻ may be a sulfonate, a carboxylate, an anion of a sulfonamide, an anion of a sulfonimide, or a methide anion.

In Formula (8), adjacent two or more of R³⁷ to R⁴⁰ optionally form a ring with each other via one or more divalent linking groups, wherein each of the one or more divalent linking groups is substituted or unsubstituted, and wherein the ring is substituted or unsubstituted. The ring may be aromatic or non-aromatic.

In Formula (8), Y and Z each independently include an electron withdrawing group. Exemplary electron withdrawing groups include, but are not limited to, cyano (including C(CN)₂ and N—CN), pyridinium, oxo, nitro, thiol, disulfide, halogen, haloalkyl, an ester group, a sulfone group, a sulfonamide group, a sulfonimide group, a phthalimide group, and a naphthalimide group.

In Formula (9), adjacent two or more of R⁴¹ to R⁴⁶ optionally form a ring with each other via one or more divalent linking groups, wherein each of the one or more divalent linking groups is substituted or unsubstituted, and wherein the ring is substituted or unsubstituted. For example, adjacent two or more of R⁴¹ to R⁴³ optionally form a ring with each other via one or more divalent linking groups, wherein each of the one or more divalent linking groups is substituted or unsubstituted, and wherein the ring is substituted or unsubstituted; and/or adjacent two or more of R⁴⁴ to R⁴⁶ optionally form a ring with each other via one or more divalent linking groups, wherein each of the one or more divalent linking groups is substituted or unsubstituted, and wherein the ring is substituted or unsubstituted.

In Formula (10), adjacent two or more of R⁴⁷ to R⁵¹ optionally form a ring with each other via one or more divalent linking groups, wherein each of the one or more divalent linking groups is substituted or unsubstituted, and wherein the ring is substituted or unsubstituted.

In Formula (11), R⁵² and R⁵³ may not be connected to each other to form a ring via a linking group.

In Formula (12), adjacent two or more of R⁵⁴ to R⁵⁵ optionally form a ring with each other via one or more divalent linking groups, wherein each of the one or more divalent linking groups is substituted or unsubstituted, and wherein the ring is substituted or unsubstituted. For example, adjacent two or more of R⁵⁴ optionally form a ring with each other via one or more divalent linking groups, wherein each of the one or more divalent linking groups is substituted or unsubstituted, and wherein the ring is substituted or unsubstituted; and/or adjacent two or more of R⁵⁵ optionally form a ring with each other via one or more divalent linking groups, wherein each of the one or more divalent linking groups is substituted or unsubstituted, and wherein the ring is substituted or unsubstituted.

In Formula (12), X includes an electron withdrawing group. Exemplary electron withdrawing groups include, but are not limited to, cyano (including C(CN)₂ and N—CN), pyridinium, oxo, nitro, thiol, disulfide, halogen, haloalkyl, an ester group, a sulfone group, a sulfonamide group, a sulfonimide group, a phthalimide group, and a naphthalimide group.

In Formula (12), n1 and n2 are each independently an integer from 0 to 4. Typically, n1 and n2 are each independently 0 or 1.

In Formula (13), adjacent two or more of R⁵⁶ to R⁵⁷ optionally form a ring with each other via one or more divalent linking groups, wherein each of the one or more divalent linking groups is substituted or unsubstituted, and wherein the ring is substituted or unsubstituted. For example, adjacent two or more of R⁵⁶ optionally form a ring with each other via one or more divalent linking groups, wherein each of the one or more divalent linking groups is substituted or unsubstituted, and wherein the ring is substituted or unsubstituted, and/or adjacent two or more of R⁵⁷ optionally form a ring with each other via one or more divalent linking groups, wherein each of the one or more divalent linking groups is substituted or unsubstituted, and wherein the ring is substituted or unsubstituted.

In Formula (13), n4 and n5 are each independently an integer from 0 to 2. Typically, n4 and n5 are each independently 0 or 1.

In Formula (14), adjacent two or more of R⁵⁸ to R⁵⁹ optionally form a ring with each other via one or more divalent linking groups, wherein each of the one or more divalent linking groups is substituted or unsubstituted, and wherein the ring is substituted or unsubstituted. For example, adjacent two or more of R⁵⁸ optionally form a ring with each other via one or more divalent linking groups, wherein each of the one or more divalent linking groups is substituted or unsubstituted, and wherein the ring is substituted or unsubstituted, and/or adjacent two or more of R⁵⁹ optionally form a ring with each other via one or more divalent linking groups, wherein each of the one or more divalent linking groups is substituted or unsubstituted, and wherein the ring is substituted or unsubstituted.

In Formula (14), n6 and n7 are each independently an integer from 0 to4. Typically, n6 and n7 are each independently 0 or 1.

In Formula (15), adjacent two or more of R⁶⁰ to R⁶¹ optionally form a ring with each other via one or more divalent linking groups, wherein each of the one or more divalent linking groups is substituted or unsubstituted, and wherein the ring is substituted or unsubstituted. For example, adjacent two or more of R⁶⁰ optionally form a ring with each other via one or more divalent linking groups, wherein each of the one or more divalent linking groups is substituted or unsubstituted, and wherein the ring is substituted or unsubstituted; and/or adjacent two or more of R⁶¹ optionally form a ring with each other via one or more divalent linking groups, wherein each of the one or more divalent linking groups is substituted or unsubstituted, and wherein the ring is substituted or unsubstituted.

In Formula (15), n8 and n9 are each independently an integer from 0 to 4. Typically, n8 and n9 are each independently 0 or 1.

In Formula (16), adjacent two or more of R⁶⁴ to R⁶⁵ optionally form a ring with each other via one or more divalent linking groups, wherein each of the one or more divalent linking groups is substituted or unsubstituted, and wherein the ring is substituted or unsubstituted. For example, adjacent two or more of R⁶⁴ optionally form a ring with each other via one or more divalent linking groups, wherein each of the one or more divalent linking groups is substituted or unsubstituted, and wherein the ring is substituted or unsubstituted, and/or adjacent two or more of R⁶⁵ optionally form a ring with each other via one or more divalent linking groups, wherein each of the one or more divalent linking groups is substituted or unsubstituted, and wherein the ring is substituted or unsubstituted.

In Formula (16), each l is independently an integer from 0 to 4. Typically, l is each independently 0 or 1.

In Formula (17), adjacent two or more of R⁶⁸ optionally form a ring with each other via one or more divalent linking groups, wherein each of the one or more divalent linking groups is substituted or unsubstituted, and wherein the ring is substituted or unsubstituted.

In Formula (17), l is an integer from 0 to 4. Typically, l is 0 or 1.

In Formula (18), adjacent two or more of R⁷⁰ optionally form a ring with each other via one or more divalent linking groups, wherein each of the one or more divalent linking groups is substituted or unsubstituted, and wherein the ring is substituted or unsubstituted.

In Formula (18), l is an integer from 0 to 4. Typically, l is 0 or 1.

In Formula (19), adjacent two or more of R⁷¹ optionally form a ring with each other via one or more divalent linking groups, wherein each of the one or more divalent linking groups is substituted or unsubstituted, and wherein the ring is substituted or unsubstituted.

In Formula (19), l is an integer from 0 to 4. Typically, l is 0 or 1.

In Formula (20), adjacent two or more of R⁷³ optionally form a ring with each other via one or more divalent linking groups, wherein each of the one or more divalent linking groups is substituted or unsubstituted, and wherein the ring is substituted or unsubstituted.

In Formula (21), adjacent two or more of R⁷³ optionally form a ring with each other via one or more divalent linking groups, wherein each of the one or more divalent linking groups is substituted or unsubstituted, and wherein the ring is substituted or unsubstituted.

In Formula (21), M is a transition metal. Exemplary transition metals include, but are not limited to, Cu, Zn, Co, Fe, Mn, or the like. Typically, M is Zn.

In Formula (22), adjacent two or more of R⁷⁴ optionally form a ring with each other via one or more divalent linking groups, wherein each of the one or more divalent linking groups is substituted or unsubstituted, and wherein the ring is substituted or unsubstituted.

In Formula (22), k is an integer from 0 to 30. Typically, k is 0 or 1.

In Formula (23), adjacent two or more of R⁷⁵ optionally form a ring with each other via one or more divalent linking groups, wherein each of the one or more divalent linking groups is substituted or unsubstituted, and wherein the ring is substituted or unsubstituted.

In Formula (23), each p is independently an integer from 0 to 4. Typically, each p is independently is 0 or 1.

In Formula (24), adjacent two or more of R⁷⁶ to R⁷⁷ optionally form a ring with each other via one or more divalent linking groups, wherein each of the one or more divalent linking groups is substituted or unsubstituted, and wherein the ring is substituted or unsubstituted. For example, adjacent two or more of R⁷⁶ optionally form a ring with each other via one or more divalent linking groups, wherein each of the one or more divalent linking groups is substituted or unsubstituted, and wherein the ring is substituted or unsubstituted, and/or adjacent two or more of R⁷⁷ optionally form a ring with each other via one or more divalent linking groups, wherein each of the one or more divalent linking groups is substituted or unsubstituted, and wherein the ring is substituted or unsubstituted.

In Formula (24), p is an integer from 0 to 4. Typically, p is 0 or 1. In Formula (24), q is an integer from 0 to 5. Typically, q is 0 or 1.

In Formula (25), adjacent two or more of R⁷⁸ to R⁷⁹ optionally form a ring with each other via one or more divalent linking groups, wherein each of the one or more divalent linking groups is substituted or unsubstituted, and wherein the ring is substituted or unsubstituted. For example, adjacent two or more of R⁷⁸ optionally form a ring with each other via one or more divalent linking groups, wherein each of the one or more divalent linking groups is substituted or unsubstituted, and wherein the ring is substituted or unsubstituted, and/or adjacent two or more of R⁷⁹ optionally form a ring with each other via one or more divalent linking groups, wherein each of the one or more divalent linking groups is substituted or unsubstituted, and wherein the ring is substituted or unsubstituted.

In Formula (25), X and Y each independently includes an electron withdrawing group. Exemplary electron withdrawing groups include, but are not limited to, cyano (including C(CN)₂ and N—CN), pyridinium, oxo, nitro, thiol, disulfide, halogen, haloalkyl, an ester group, a sulfone group, a sulfonamide group, a sulfonimide group, a phthalimide group, and a naphthalimide group.

In Formula (25), r is an integer from 0 to 4. Typically, r is 0 or 1. In Formula (25), q is an integer from 0 to 5. Typically, q is 0 or 1.

In Formula (26), adjacent two or more of R⁸⁰ to R⁸¹ optionally form a ring with each other via one or more divalent linking groups, wherein each of the one or more divalent linking groups is substituted or unsubstituted, and wherein the ring is substituted or unsubstituted. For example, adjacent two or more of R⁸⁰ optionally form a ring with each other via one or more divalent linking groups, wherein each of the one or more divalent linking groups is substituted or unsubstituted, and wherein the ring is substituted or unsubstituted, and/or adjacent two or more of R⁸¹ optionally form a ring with each other via one or more divalent linking groups, wherein each of the one or more divalent linking groups is substituted or unsubstituted, and wherein the ring is substituted or unsubstituted.

In Formula (26), X and Y each independently includes an electron withdrawing group. Exemplary electron withdrawing groups include, but are not limited to, cyano (including C(CN)₂ and N—CN), pyridinium, oxo, nitro, thiol, disulfide, halogen, haloalkyl, an ester group, a sulfone group, a sulfonamide group, a sulfonimide group, a phthalimide group, and a naphthalimide group.

In Formula (26), r is an integer from 0 to 4. Typically, r is 0 or 1. In Formula (25), q is an integer from 0 to 5. Typically, q is 0 or 1.

For example, in some embodiments, the non-polymeric electron acceptor compound comprises a compound represented by one of Formulae (1), (8), or (9):

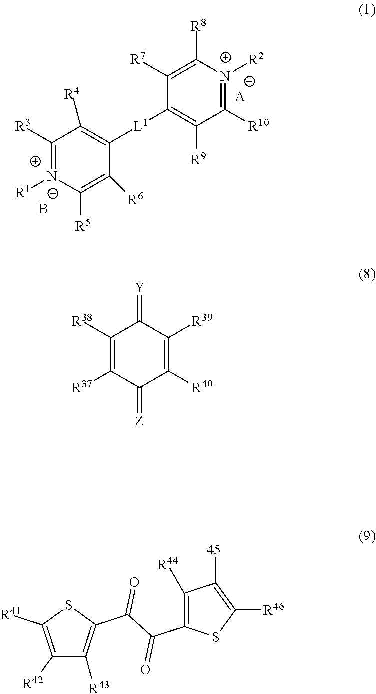

wherein Formulae (1), (8), and (9) are each as defined herein.

In some embodiments, the non-polymeric electron acceptor compound may include a compound represented by one of Formulae (27A) to (30A):

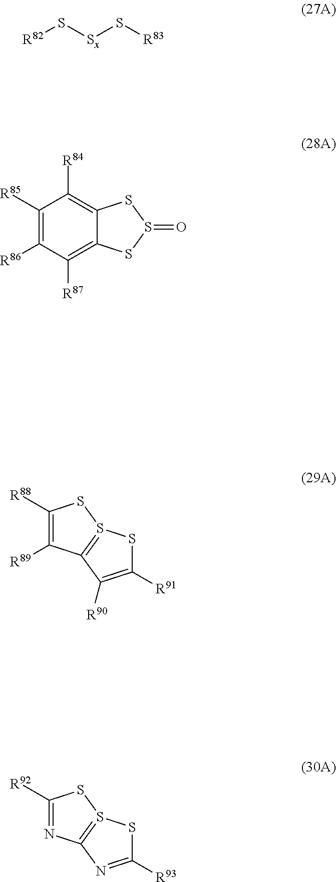

In Formula (27A), R⁸² and R⁸³ are each independently hydrogen, deuterium, halogen, nitro, amino, cyano, pyridinium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl.

In Formula (27A), each of R⁸² and R⁸³ optionally further includes one or more divalent linking groups as a part of its structure. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (27A), R⁸² and R⁸³ optionally form a ring with each other via one or more divalent linking groups, wherein each of the one or more divalent linking groups is substituted or unsubstituted, and wherein the ring is substituted or unsubstituted.

In Formula (27A), x is 1 or 2.

In Formula (28A), R⁸⁴ to R⁸⁷ are each independently hydrogen, deuterium, halogen, nitro, amino, cyano, pyridinium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl.

In Formula (28A), each of R⁸⁴ to R⁸⁷ optionally further includes one or more divalent linking groups as a part of its structure. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (28A), adjacent two or more of R⁸⁴ to R⁸⁷ optionally form a ring with each other via one or more divalent linking groups, wherein each of the one or more divalent linking groups is substituted or unsubstituted, and wherein the ring is substituted or unsubstituted.

In Formula (29A), R⁸⁸ to R⁹¹ are each independently hydrogen, deuterium, halogen, nitro, amino, cyano, pyridinium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl.

In Formula (29A), each of R⁸⁸ to R⁹¹ optionally further includes one or more divalent linking groups as a part of its structure. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (29A), adjacent two or more of R⁸⁸ to R⁹¹ optionally form a ring with each other via one or more divalent linking groups, wherein each of the one or more divalent linking groups is substituted or unsubstituted, and wherein the ring is substituted or unsubstituted.

In Formula (30A), R⁹² and R⁹³ are each independently hydrogen, deuterium, halogen, nitro, amino, cyano, pyridinium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl.

In Formula (30A), each of R⁹² and R⁹³ optionally further includes one or more divalent linking groups as a part of its structure. Exemplary divalent linking groups may be selected from —O—, —C(O)—, —C(O)O—, —S—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, deuterium, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

Non-limiting examples of the non-polymeric electron acceptor compound include the following:

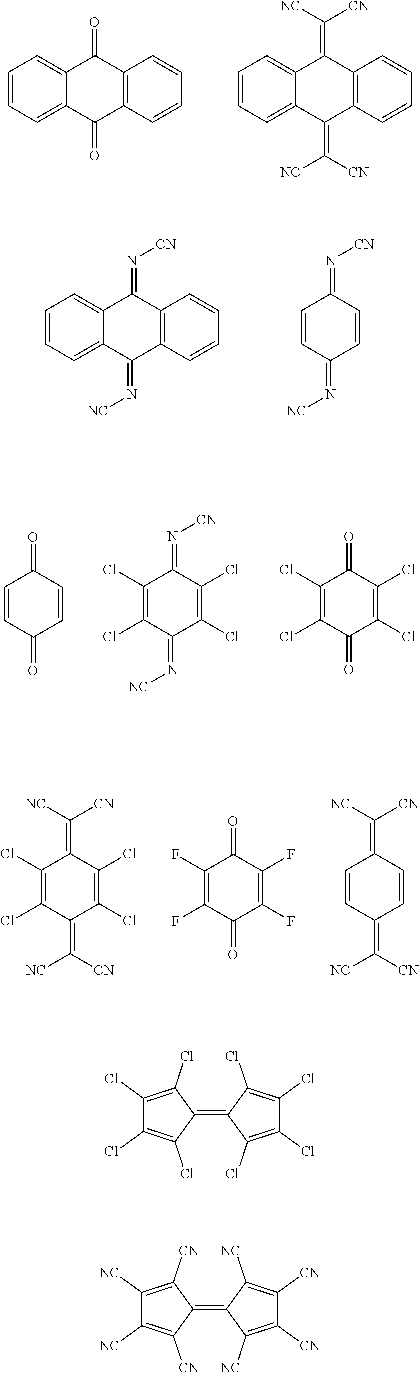

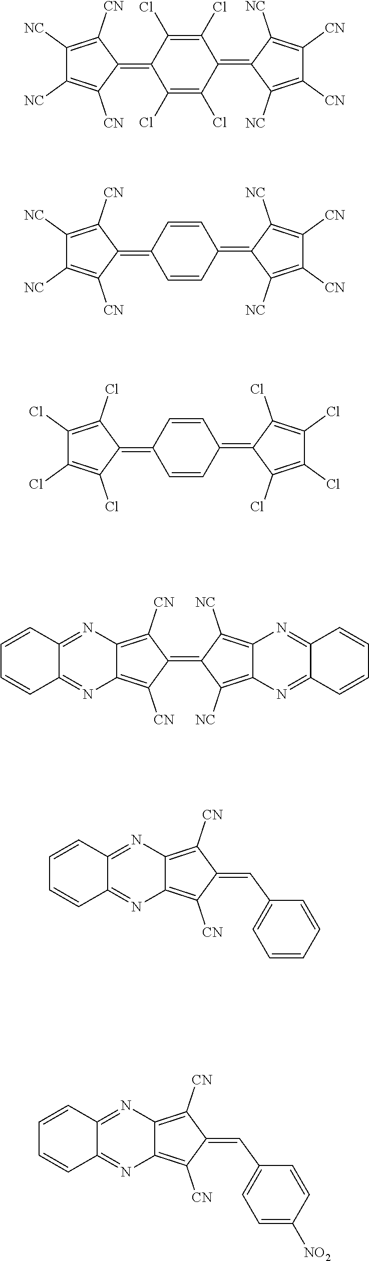 [SMILES: N#CC1=C(C#N)C(=c2c(Cl)c(Cl)c(=C3C(C#N)=C(C#N)C(C#N)=C3C#N)c(Cl)c2Cl)C(C#N)=C1C#N ; N#CC1=C(C#N)C(=c2ccc(=C3C(C#N)=C(C#N)C(C#N)=C3C#N)cc2)C(C#N)=C1C#N ; ClC1=C(Cl)C(=c2ccc(=C3C(Cl)=C(Cl)C(Cl)=C3Cl)cc2)C(Cl)=C1Cl ; N#CC1=c2nc3ccccc3nc2=C(C#N)C1=C1C(C#N)=c2nc3ccccc3nc2=C1C#N ; N#CC1=c2nc3ccccc3nc2=C(C#N)C1=Cc1ccccc1 ; N#CC1=c2nc3ccccc3nc2=C(C#N)C1=Cc1ccc([N+](=O)[O-])cc1]

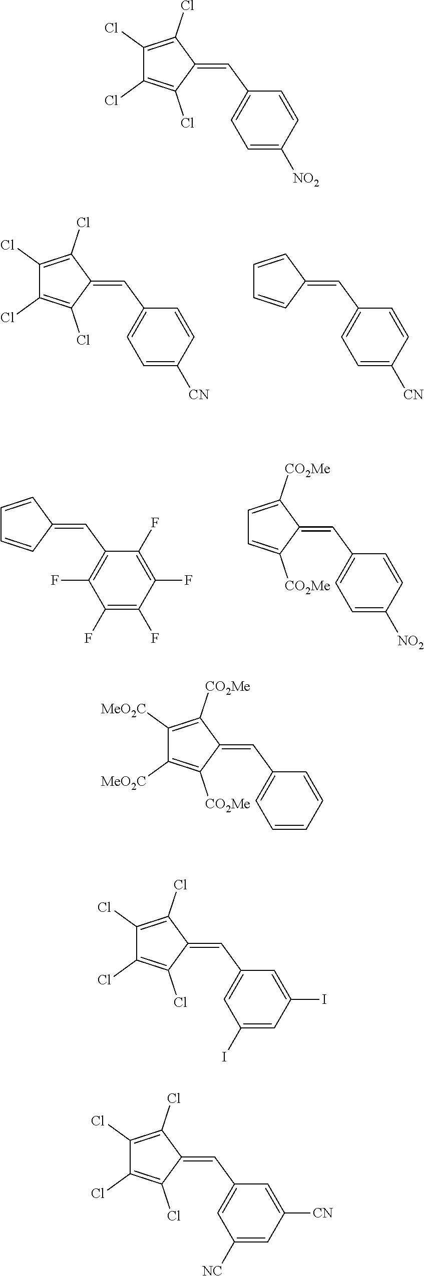

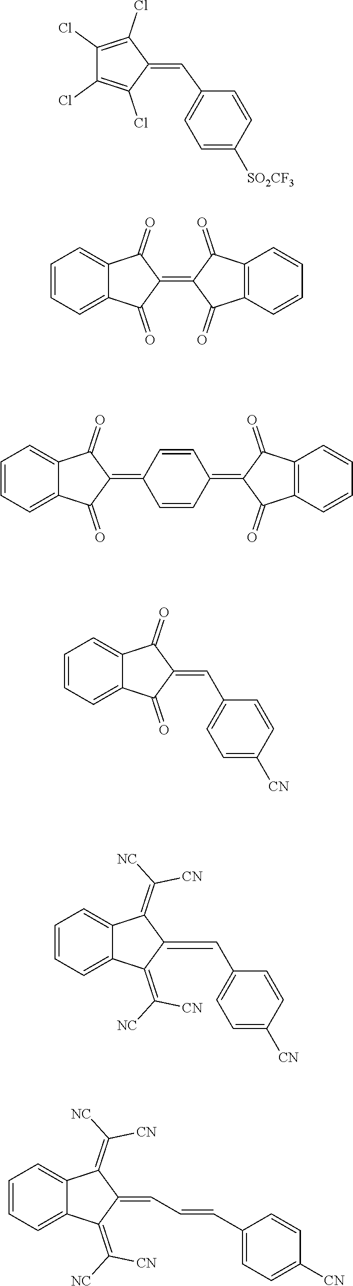

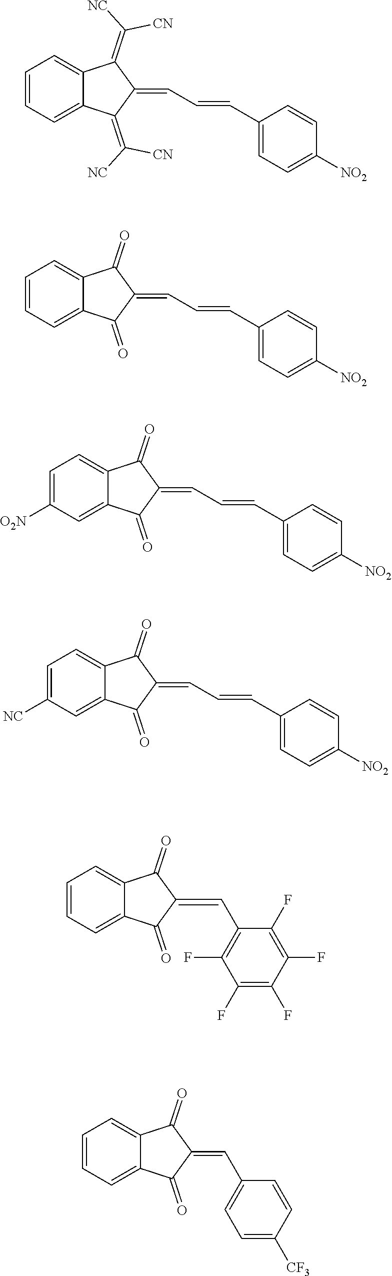 [SMILES: N#CC(C#N)=C1C(=C/C=C/c2ccc([N+](=O)[O-])cc2)C(=C(C#N)C#N)c2ccccc21 ; O=C1C(=C/C=C/c2ccc([N+](=O)[O-])cc2)C(=O)c2ccccc21 ; O=C1/C(=C/C=C/c2ccc([N+](=O)[O-])cc2)C(=O)c2cc([N+](=O)[O-])ccc21 ; N#Cc1ccc2c(c1)C(=O)/C(=C\C=C\c1ccc([N+](=O)[O-])cc1)C2=O ; O=C1C(=Cc2c(F)c(F)c(F)c(F)c2F)C(=O)c2ccccc21 ; O=C1C(=Cc2ccc(C(F)(F)F)cc2)C(=O)c2ccccc21]

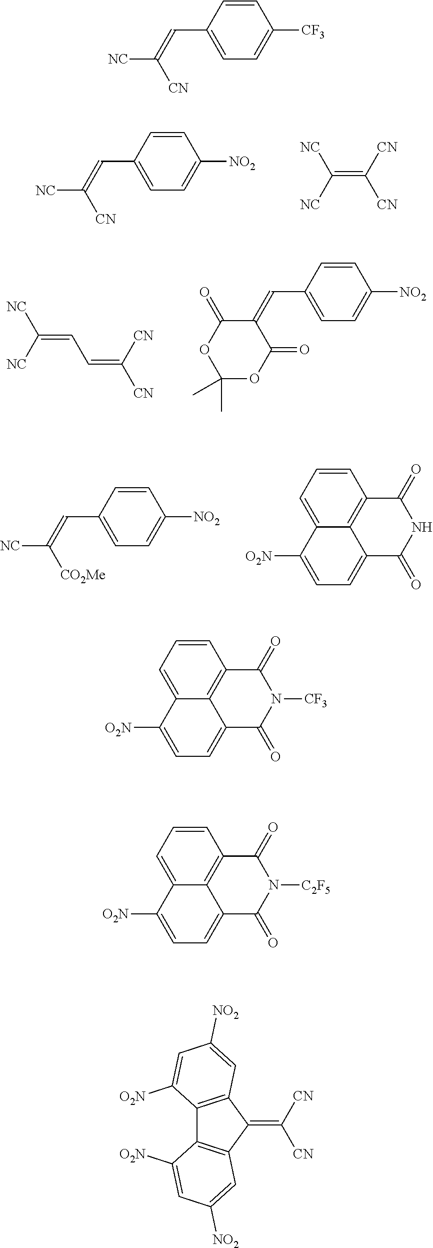

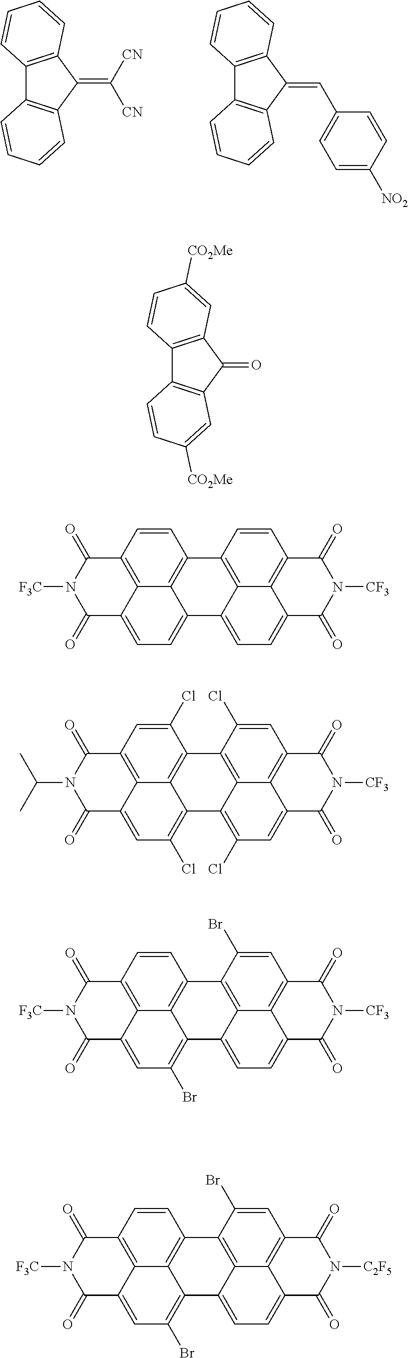

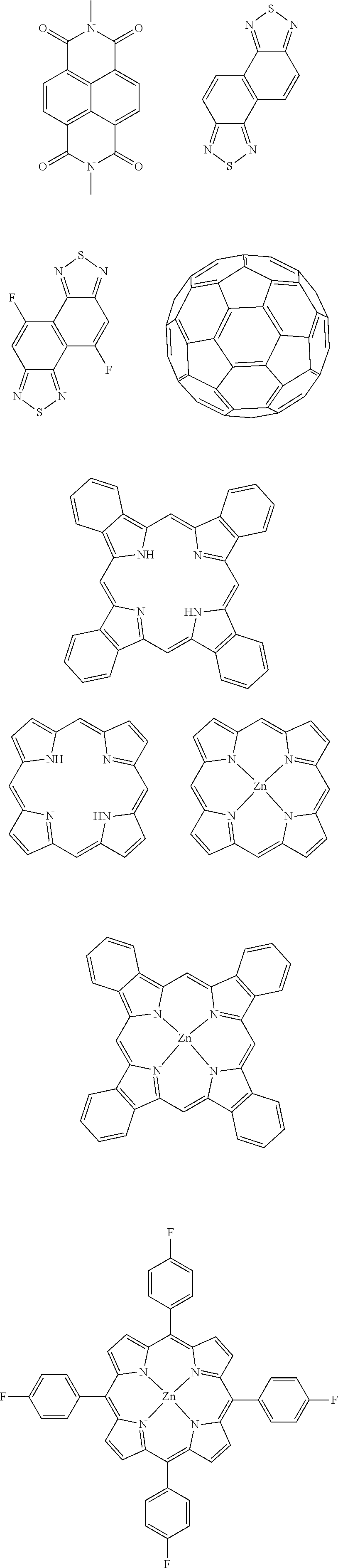

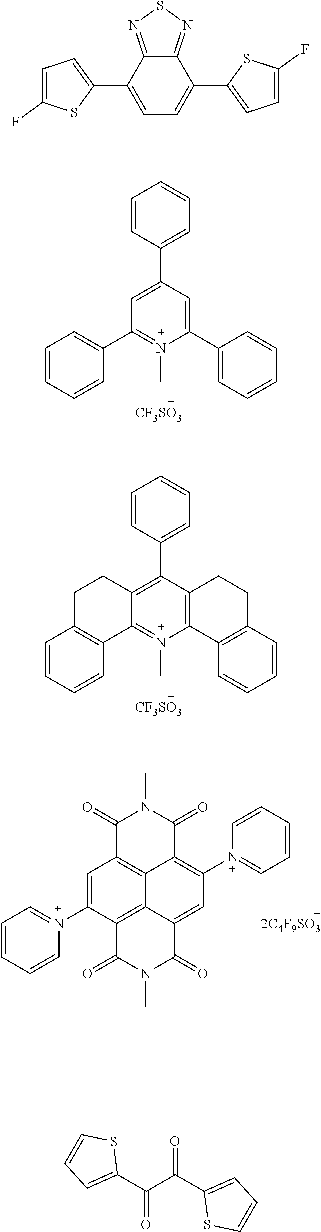

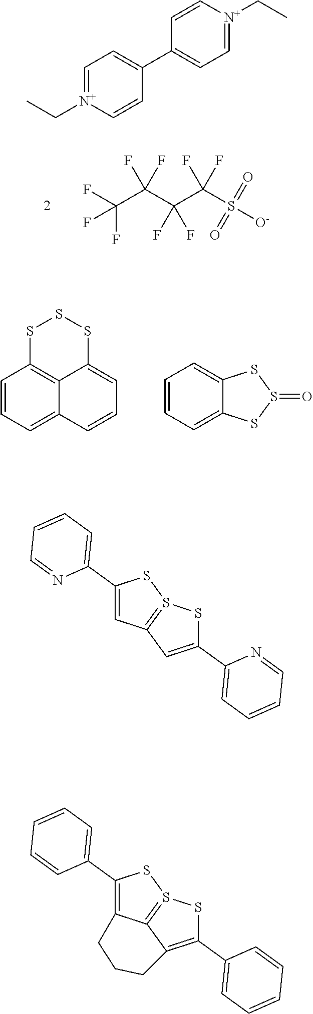 [SMILES: CC[n+]1ccc(-c2cc[n+](CC)cc2)cc1 ; O=S(=O)([O-])C(F)(F)C(F)(F)C(F)(F)C(F)(F)F ; c1cc2c3c(cccc3c1)SSS2 ; O=S1Sc2ccccc2S1 ; C1=C(c2ccccn2)SS2=C1C=C(c1ccccn1)S2 ; c1ccc(C2=C3CCCC4=C(c5ccccc5)SS(=C34)S2)cc1]

The electron acceptor compound can accept one electron, two electrons, or more, depending on its molecular structure and redox properties. When the electron acceptor compound is capable of accepting up to two electrons, it is preferred that the electron affinity of the intermediate species formed after the first electron transfer be higher than the electron affinity of the photoacid generator compound. This ensures that the second electron transfer is thermodynamically favorable and kinetically efficient, thereby promoting complete reduction of the acceptor species and therefore more efficient secondary electron quenching. A representative example of such a compound is ortho-quinone derivatives and the like. For instance, in the case of benzoquinone, the initial acceptance of one electron results in the formation of a radical anion, which can subsequently undergo further reduction by accepting a second electron to yield the corresponding dianion. This stepwise electron transfer mechanism is particularly advantageous in photochemical systems where controlled electron diffusion is critical.

Preferred electron acceptor compounds are those that suppress electron diffusion without compromising the resist sensitivity. While the quenching of secondary electrons by the electron acceptor compound can reduce the effective availability of thermal secondary electrons for photoacid generator (PAG) activation and acid formation, electron acceptor compounds of the invention can lead to a higher dissolution rate in the resist-exposed area. This enhanced dissolution rate can compensate for reduced acid generation yield, thereby boosting overall sensitivity. As a result, it is possible that resist sensitivity is not compromised, and may even be improved due to the synergistic effect of localized electron capture and enhanced solubility contrast.

In some embodiments, the composition may include two or more different non-polymer electron acceptor compounds as described herein. The two or more non-polymeric electron acceptor compounds may each have a greater electron affinity than an electron affinity of the photoacid generator compound. In still other embodiments, the two or more non-polymeric electron acceptor compounds may each have a greater electron affinity than an electron affinity of any added PDQ compound.

The non-polymer electron acceptor compounds may be prepared using any suitable methods in the art, including those described herein in the examples.

The non-polymer electron acceptor compound may be included in the composition in an amount from 0.1 to 50 wt %, preferably 1 to 40 wt %, and more preferably from 2 to 20 wt %, based on total solids of the composition.

The composition also includes an acid-sensitive polymer that includes a first repeating unit derived from a monomer comprising an acid-decomposable group.

Suitable acid decomposable or labile groups include, for example, tertiary alkyl ester groups, secondary or tertiary aryl ester groups, secondary or tertiary ester groups having a combination of alkyl and aryl groups, tertiary alkoxy groups, acetal groups, ketal groups, tertiary carbonate groups, and tertiary carbamate groups. Typically, the acid labile group may be an acetal group, a ketal group, a tertiary carbonate group, a tertiary carbamate group, or a tertiary ester group. As used herein, the “tertiary carbamate group” includes tertiary carbamate ester groups having alkyl groups, tertiary carbamate ester groups having aryl groups, and tertiary carbamate ester groups having a combination of alkyl and aryl groups. As used herein, the “tertiary carbonate group” includes tertiary carbonate ester groups having alkyl groups, tertiary carbonate ester groups having aryl groups, and tertiary carbonate ester groups having a combination of alkyl and aryl groups. Preferably, the acid liable group includes a tertiary ester group.

Exemplary repeating units having an acid labile group include those represented by one or more of Formulae (27) to (31):

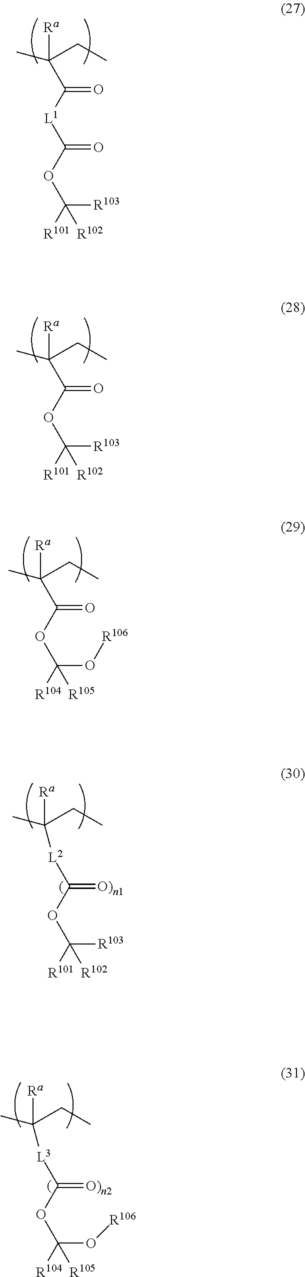

In Formulae (27) to (31), each R^{a} is independently hydrogen, deuterium, fluorine, cyano, substituted or unsubstituted C₁₋₁₀ alkyl, or substituted or unsubstituted C₁₋₁₀ fluoroalkyl. Preferably, R^{a} is hydrogen, fluorine, or substituted or unsubstituted C₁₋₅ alkyl, typically methyl.

In Formula (27), L¹ is a divalent linking group. For example, L¹ may be a divalent linking group including at least one carbon atom, at least one heteroatom, or a combination thereof. For example, L¹ may include 1 to 10 carbon atoms and at least one heteroatom. In one or more embodiments, L¹ may be —OCH₂—, —OCH₂CH₂O— or —N(R^{c})—, wherein R^{c} is hydrogen, deuterium, substituted or unsubstituted C₁₋₁₀ alkyl, substituted or unsubstituted C₁₋₁₀ heteroalkyl, substituted or unsubstituted C₆₋₁₀ aryl, or substituted or unsubstituted C₃₋₁₀ heteroaryl.

In Formulae (27), (28), and (30), R¹⁰¹ to R¹⁰³ may each independently be hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₂₋₂₀ heteroaryl; provided that only one of R¹⁰¹ to R¹⁰³ may be hydrogen, and provided that when one of R¹⁰¹ to R¹⁰³ is hydrogen, one or both of the others of R¹⁰¹ to R¹⁰³ are substituted or unsubstituted C₆₋₂₀ aryl or substituted or unsubstituted C₄₋₂₀ heteroaryl. Preferably, R¹⁰¹ to R¹⁰³ are each independently substituted or unsubstituted C₁₋₆ alkyl or substituted or unsubstituted C₃₋₁₀ cycloalkyl.

In Formulae (27), (28), and (30), any two of R¹⁰¹ to R¹⁰³ together optionally form a ring, and each of R¹⁰¹ to R¹⁰³ optionally may include as part of their structure one or more groups chosen from —O—, —C(O)—, —N(R^{c})—, —S—, —S(O)—, or —S(O)₂—, wherein R^{c} may be hydrogen, deuterium, a straight chain or branched C₁₋₂₀ alkyl, monocyclic or polycyclic C₃₋₂₀ cycloalkyl, or monocyclic or polycyclic C₁₋₂₀ heterocycloalkyl. For example, any one or more of R¹⁰¹ to R¹⁰³ may be independently a group of the formula —CH₂C(═O)CH₍₃₋ₙ₎Yₙ, where each Y is independently substituted or unsubstituted C₁₋₃₀ heterocycloalkyl, and n is 1 or 2. For example, each Y may be independently substituted or unsubstituted C₁₋₃₀ heterocycloalkyl including a group of the formula —O(C^{a1})(C^{a2})O—, wherein C^{a1} and C^{a2} are each independently hydrogen, deuterium or substituted or unsubstituted C₁₋₁₀ alkyl, and where C^{a1} and C^{a2} together optionally form a ring.

In Formulae (29) and (31), R¹⁰⁴ and R¹⁰⁵ may be each independently hydrogen, deuterium, substituted or unsubstituted C₁₋₂₀ alkyl, substituted or unsubstituted C₃₋₂₀ cycloalkyl, substituted or unsubstituted C₁₋₂₀ heterocycloalkyl, substituted or unsubstituted C₆₋₂₀ aryl, or substituted or unsubstituted C₂₋₂₀ heteroaryl; and R¹⁰⁶ may be substituted or unsubstituted C₁₋₂₀ alkyl, substituted or unsubstituted C₃₋₂₀ cycloalkyl, or substituted or unsubstituted C₁₋₃₀ heterocycloalkyl. Optionally, one of R¹⁰⁴ or R¹⁰⁵ together with R¹⁰⁶ may form a heterocyclic ring. Preferably, R¹⁰⁴ and R¹⁰⁵ may be each independently hydrogen, deuterium, substituted or unsubstituted C₁₋₂₀ alkyl, substituted or unsubstituted C₃₋₂₀ cycloalkyl, or substituted or unsubstituted C₁₋₂₀ heterocycloalkyl.

In Formulae (30) and (31), L² and L³ are each independently a single bond or a divalent linking group. Preferably, L² and L³ are each independently substituted or unsubstituted C₆₋₃₀ arylene or substituted or unsubstituted C₃₋₃₀ cycloalkylene. For example, in some embodiments, L³ does not include a (meth)acrylate group as part of its structure.

In Formulae (30) and (31), each of n1 and n2 may independently be 0 or 1. It is to be understood that when n1 or n2 is 0, the corresponding L² or L³ group is connected directly to the respective oxygen atom.

Non-limiting examples of repeating units having an acid labile group include the following:

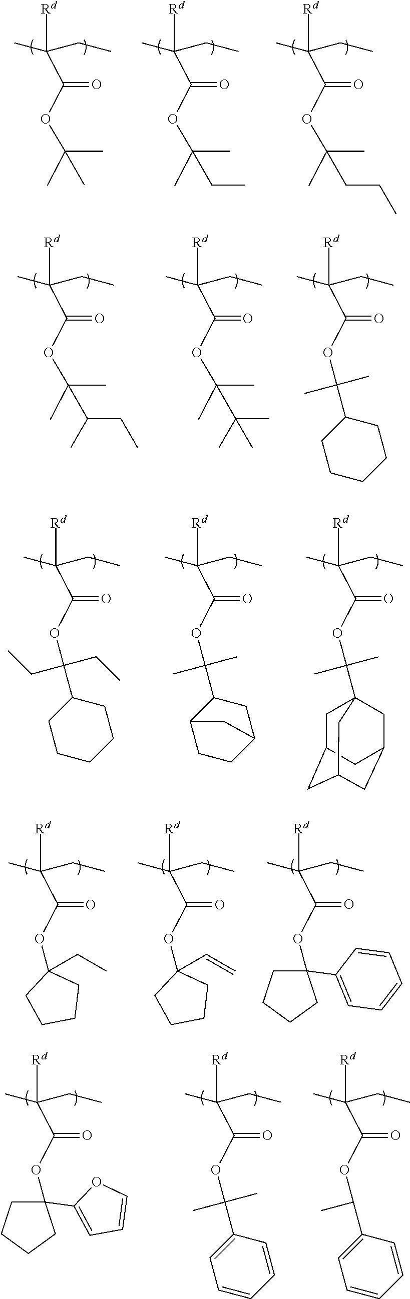

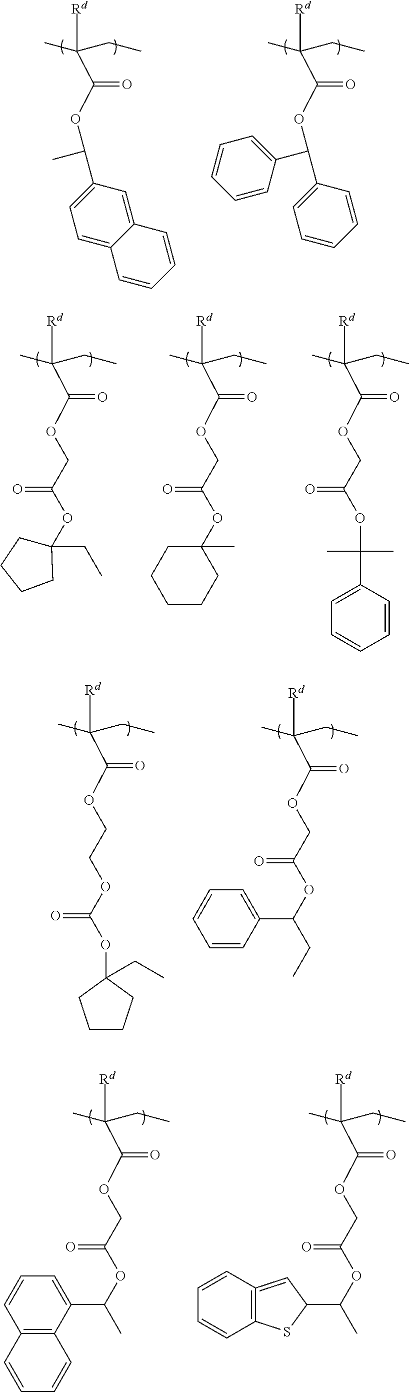

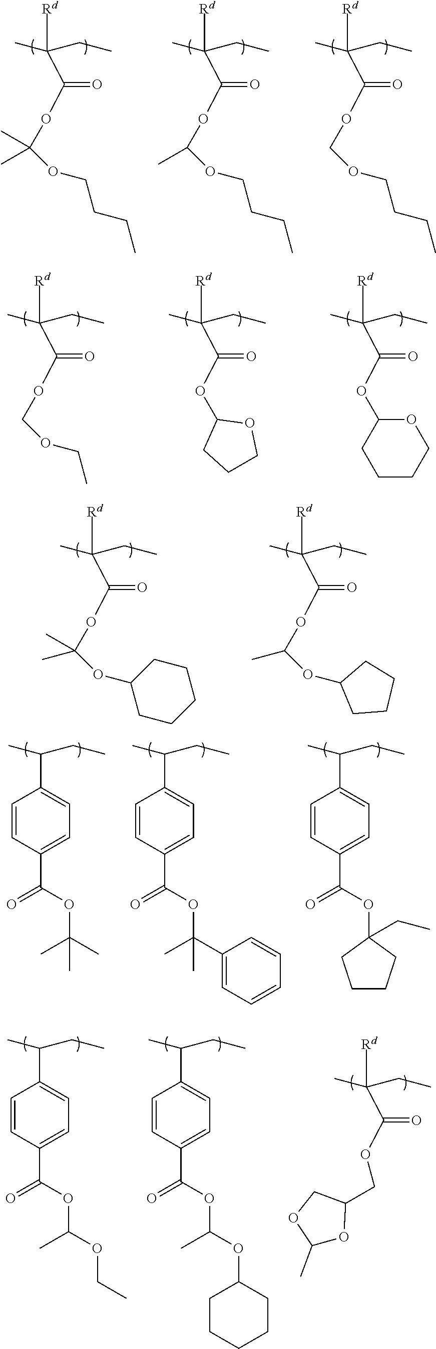

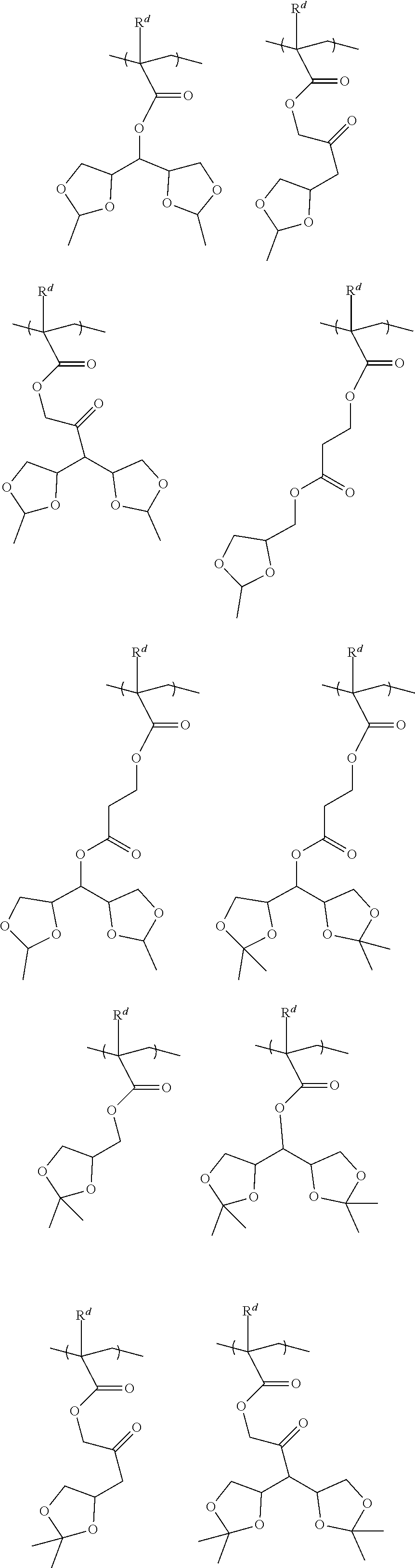

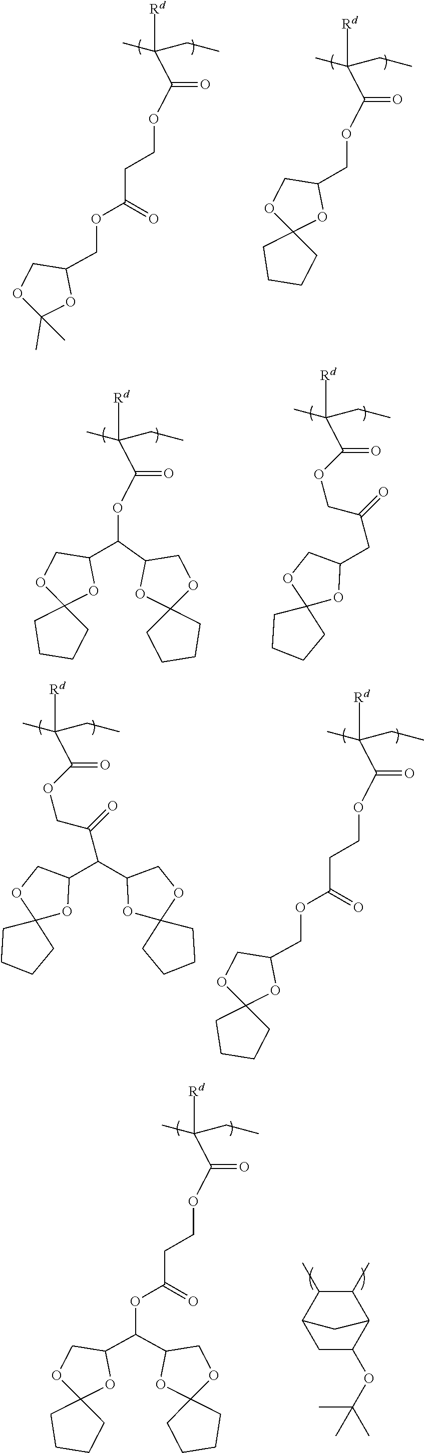

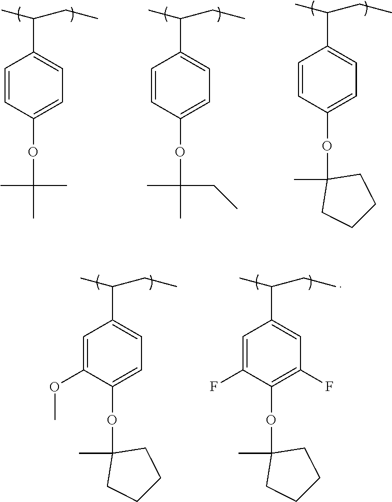

wherein R^{d} is hydrogen, deuterium, halogen, substituted or unsubstituted C₁₋₆ alkyl, or substituted or unsubstituted C₃₋₆ cycloalkyl.

The repeating unit having an acid-labile group is present in the polymer in an amount from 25 to 75 mol %, more typically from 25 to 50 mol %, still more typically from 30 to 50 mol %, based on total repeating units in the polymer.

The polymer may further include one or more additional repeating units. The repeating units may be, for example, one or more units for purposes of adjusting properties of the composition, such as etch rate and solubility. Exemplary repeating units may include those derived from one or more of (meth)acrylate, vinyl aromatic, vinyl ether, vinyl ketone, and/or vinyl ester monomers. The polymer of the composition may be a homopolymer or a copolymer that includes two or more structurally different repeating units. For example, the polymer may include one or more repeating units that include a functional group selected from a hydroxyaryl group, a base-solubilizing group, a lactone-containing group, a sultone-containing group, a polar group, a crosslinkable group, a crosslinking group, or the like, or a combination thereof.

A repeating unit of the polymer may include a hydroxyaryl group. Exemplary hydroxyaryl groups include a phenolic group or a naphtholic group. For example, a repeating unit of the polymer may include a hydroxyaryl group that is represented by Formula (32):

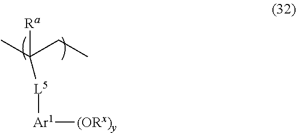

In Formula (32), R^{a} may be hydrogen, deuterium, fluorine, cyano, or substituted or unsubstituted C₁₋₁₀ alkyl. Preferably, R^{a} may be hydrogen, deuterium, fluorine, or substituted or unsubstituted C₁₋₅ alkyl, typically hydrogen or methyl.

In Formula (32), L⁵ may be a single bond or one or more divalent linking groups. For example, L⁵ may be —O—, —C(O)—, —C(O)O—, —N(R^{c})—, —C(O)N(R^{c})—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R^{c} may be hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl. In some aspects, L⁵ may be a single bond, or one or more groups selected from —C(O)O—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof.

In Formula (32), Ar¹ may be a substituted C₅₋₆₀ aromatic group that optionally includes one or more aromatic ring heteroatoms chosen from N, O, S, or a combination thereof, wherein the aromatic group may be monocyclic, non-fused polycyclic, or fused polycyclic. When the C₅₋₆₀ aromatic group is polycyclic, the ring or ring groups may be fused (such as naphthyl or the like), non-fused, or a combination thereof. When the polycyclic C₅₋₆₀ aromatic group is non-fused, the ring or ring groups may be directly linked (such as biaryls, biphenyl, or the like) or may be bridged by a heteroatom (such as triphenylamino or diphenylene ether). In some aspects, the polycyclic C₅₋₆₀ aromatic group may include a combination of fused rings and directly linked rings (such as binaphthyl or the like).

In Formula (32), y may be an integer from 1 to 12, preferably from 1 to 6, and typically from 1 to 3.

In Formula (32), each R^{x} may independently be hydrogen or methyl, provided that at least one R^{x} is hydrogen.

Non-limiting examples of such repeating units of Formula (32) may include:

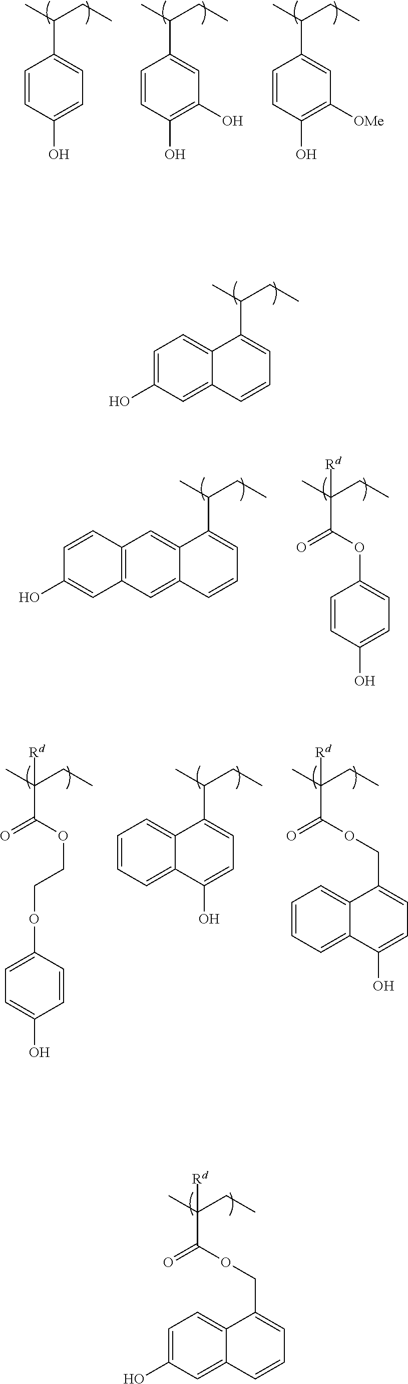

wherein R^{d} may be hydrogen, deuterium, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

The repeating unit in the polymer including a hydroxyaryl group typically may be present in an amount from 10 to 90 mole percent (mol %), more typically from 15 to 75 mol %, and still more typically from 20 to 70 mol %, based on total repeating units of the polymer. The repeating units including a hydroxyaryl group typically may be present in the polymer in an amount from 10 to 90 mol %, more typically from 15 to 75 mol %, and still more typically from 25 to 70 mol %, based on total repeating units of the polymer.

A repeating unit of the polymer may include a lactone group. For example, a repeating unit of the polymer may include a lactone group that is represented by Formula (33):

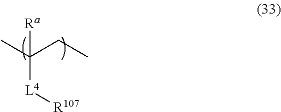

In Formula (33), R^{a} may be hydrogen, deuterium, fluorine, cyano, or substituted or unsubstituted C₁₋₁₀ alkyl. Preferably, R^{a} may be hydrogen, fluorine, or substituted or unsubstituted C₁₋₅ alkyl, typically hydrogen or methyl.

In Formula (33), L⁴ may be a single bond or one or more divalent linking groups. For example, L⁴ may be —O—, —C(O)—, —C(O)O—, —N(R^{c})—, —C(O)N(R^{c})—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R^{c} may be hydrogen, deuterium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl. In some aspects, L⁴ may be a single bond, or one or more groups selected from —C(O)O—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof.

In Formula (33), R¹⁰7 may be a monocyclic, polycyclic, or fused polycyclic C₄₋₂₀ lactone-containing group.

Non-limiting examples of lactone-containing repeating units of Formula (33) may include:

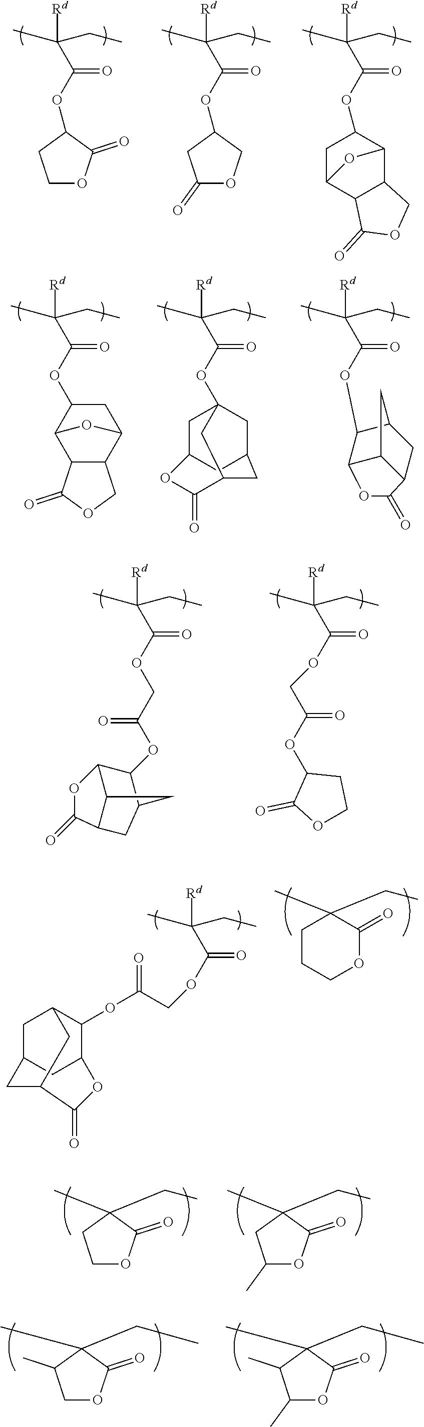

wherein R^{d} may be hydrogen, deuterium, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

A repeating unit including a lactone group typically may be present in an amount from 5 to 90 mol %, more typically from 10 to 75 mol %, and still more typically from 15 to 70 mol %, based on total repeating units of the polymer. The repeating units including a lactone group typically may be present in the polymer in an amount from 5 to 90 mol %, more typically from 10 to 75 mol %, and still more typically from 15 to 70 mol %, based on total repeating units of the polymer.

A repeating unit of the polymer may include a salt group. As used herein, a “salt group” refers to a moiety having a positive charge and/or a negative charge, such as having a positively charged or negatively charged moiety that is bonded pendant to the backbone of the block copolymer. The repeating unit of the block copolymer including a salt group may comprise a photoacid generator (PAG) group or a photo-decomposable quencher (PDQ) group. For example, a repeating unit of the polymer may include a salt group that is represented by Formulae (34a) or (34b):

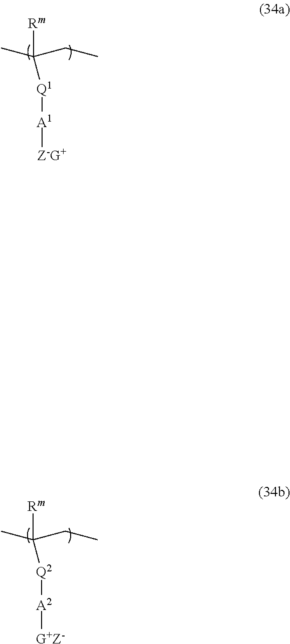

In Formulae (34a) and (34b), each R^{m} may be hydrogen, deuterium, fluorine, cyano, or substituted or unsubstituted C₁₋₁₀ alkyl. Preferably, R^{m} is hydrogen, fluorine, or substituted or unsubstituted C₁₋₅ alkyl, typically methyl.

In Formulae (34a) and (34b), Q¹ and Q² may each be independently a single bond or a divalent linking group. Preferably, Q¹ and Q² may each independently include 1 to 10 carbon atoms and at least one heteroatom, more preferably —C(O)—O—.

In Formulae (34a) and (34b), A¹ and A² may be each independently one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, or substituted or unsubstituted C₃₋₃₀ heteroarylene. In some embodiments, A¹ and A² may be each independently a divalent C₁₋₃₀ perfluoroalkylene group that is optionally substituted.

In Formula (34a), Z⁻ is an anionic moiety that is bonded to A¹, the conjugated acid of which typically has a pKa from −15 to 10. Z⁻ may be a sulfonate, a carboxylate, an anion of a sulfonamide, an anion of a sulfonimide, or a methide anion.

In Formula (34a), G⁺ is an organic cation as defined herein. In some embodiments, G⁺ is an iodonium cation substituted with two alkyl groups, two aryl groups, or a combination of alkyl and aryl groups; or a sulfonium cation substituted with three alkyl groups, three aryl groups, or a combination of alkyl and aryl groups.

In Formula (34b), Z⁻ is an anion compound as defined herein, the conjugated acid of which typically has a pKa from −15 to 10. Z⁻ may be a sulfonate, a carboxylate, an anion of a sulfonamide, an anion of a sulfonimide, or a methide anion species. For example, Z⁻ may be as defined herein for the anions A⁻.

In Formula (34b), G⁺ is an organic cation that is bonded to A². For example, G⁺ may include an iodonium cation substituted with two alkyl groups, two aryl groups, or a combination of alkyl and aryl groups; or a sulfonium cation substituted with three alkyl groups, three aryl groups, or a combination of alkyl and aryl groups.

In still other embodiments, when the polymer includes a repeating unit having a salt group, the polymer may include a zwitterionic species. For example, the polymer may include repeating units having a salt group of the Formula (34c):

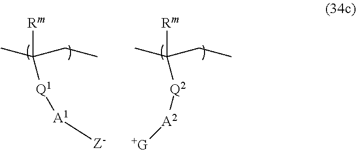

wherein, in Formula (34c), each R^{m} is independently as defined for Formulae (34a) and (34b).

In Formula (34c), Q¹, A¹, and Z⁻ are as defined in Formula (20a), and Q², A², and G⁺ are as defined in Formula (34b).

Exemplary repeating units of Formula (34a) include the following:

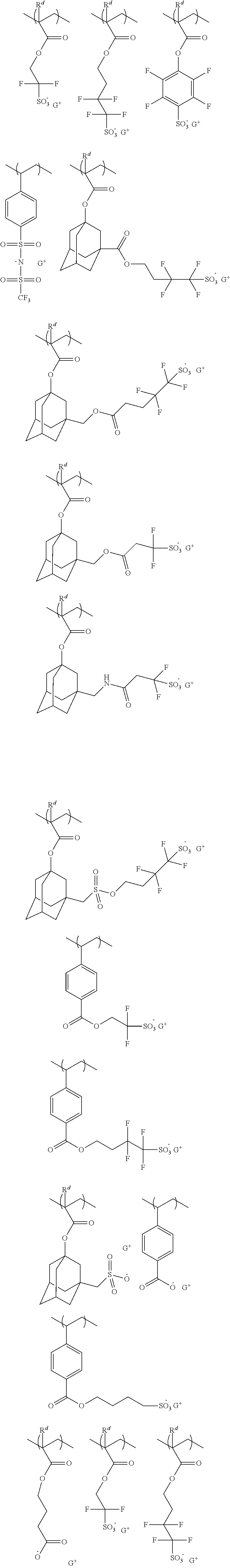

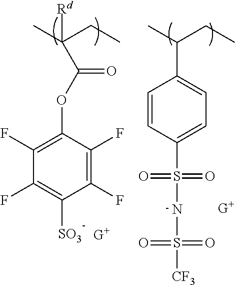

wherein G is the organic cation, and each R^{d} is independently as defined for Formulae (34a).

Exemplary repeating units of Formula (34b) include the following:

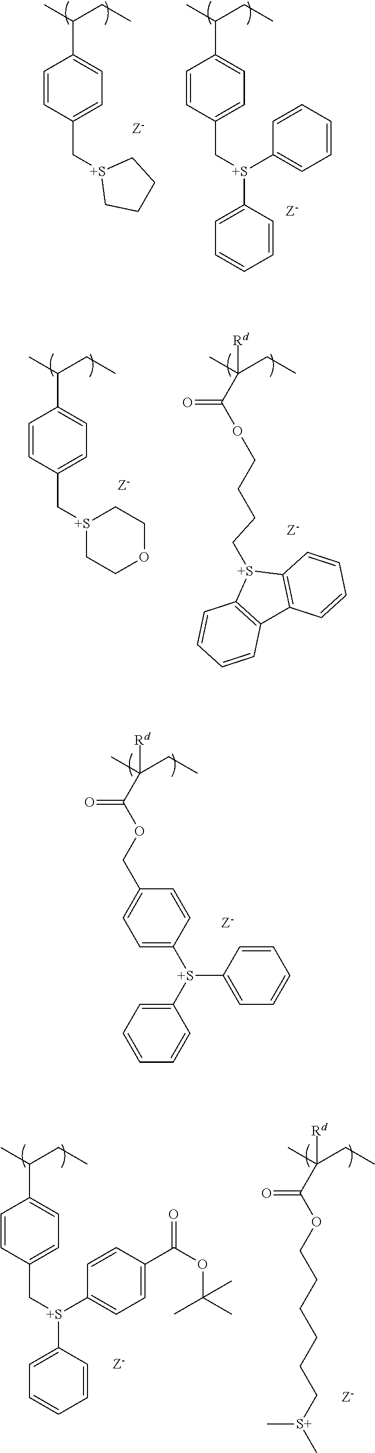

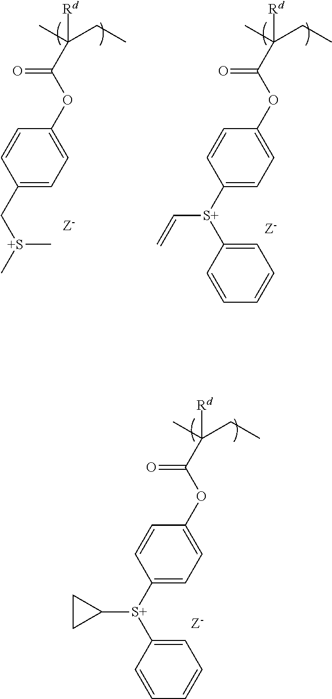

wherein Z⁻ is an anion group as defined herein, and each R^{d} is independently as defined for Formulae (34b).

The repeating unit of the polymer including a salt typically may be present in an amount from 1 to 35 mol %, typically from 1 to 25 mol %, more typically from 2 to 15 mol %, based on total repeating units of the polymer. The repeating units including a salt may be present in the polymer in an amount from 1 to 35 mol %, typically from 1 to 25 mol %, more typically from 2 to 15 mol %, based on total repeating units of the polymer.

In some embodiments, the polymer may include a repeating unit that includes a polar group. Exemplary polar groups include a cyano group, a sultone group, a sulfonamide group, a hydroxyalkyl group, a hydroxycycloalkyl group, or a combination thereof. It is to be understood that some groups, such as a lactone group or a hydroxyaryl group, may be considered to be a polar group, however, these groups are differentiated from the polar groups as used herein.

A repeating unit of the polymer may include a polar group that is represented by Formula (35):

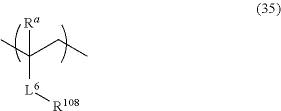

In Formula (35), R^{a} may be hydrogen, deuterium, fluorine, cyano, or substituted or unsubstituted C₁₋₁₀ alkyl. Preferably, R^{a} may be hydrogen, fluorine, or substituted or unsubstituted C₁₋₅ alkyl, typically hydrogen or methyl.

In Formulae (35), L⁶ may be a single bond or one or more divalent linking groups. For example, L⁶ may be —O—, —C(O)—, —C(O)O—, —N(R^{c})—, —C(O)N(R^{c})—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R^{c} may be hydrogen, deuterium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl. In some aspects, L⁶ may be a single bond, or one or more groups selected from —C(O)O—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof.

In Formula (35), R¹⁰⁸ may be substituted or unsubstituted C₁₋₁₀₀ or C₁₋₂₀ alkyl, typically C₁₋₁₂ alkyl; substituted or unsubstituted C₃₋₃₀ or C₃₋₂₀ cycloalkyl; or substituted or unsubstituted poly(C₁₋₃ alkylene oxide). The substituted C₁₋₁₀₀ or C₁₋₂₀ alkyl, the substituted C₃₋₃₀ or C₃₋₂₀ cycloalkyl, and the substituted poly(C₁₋₃ alkylene oxide) are substituted with one or more of a sulfonamide group (e.g., —NHSO₂CF₃), a hydroxy group (—OH), or a fluoroalcohol group (e.g., —C(CF₃)₂OH).

Non-limiting examples of repeating units of Formula (35) may include:

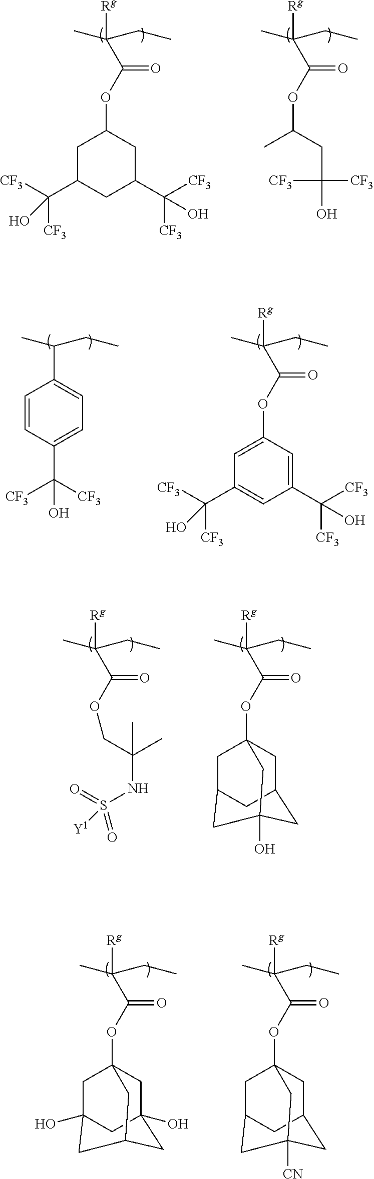

wherein R^{g} may be hydrogen, deuterium, fluorine, cyano, or substituted or unsubstituted C₁₋₁₀ alkyl. Preferably, R^{g} may be hydrogen, fluorine, or substituted or unsubstituted C₁₋₅ alkyl, typically methyl. Y¹ may be F or C₁₋₄ perfluoroalkyl.

In some embodiments, the polymer may include a repeating unit that includes an acid group. Exemplary acid groups include a carboxylic acid group. A repeating unit of the polymer may include an acid group that is represented by Formula (36):

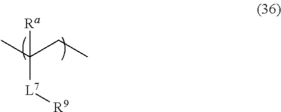

In Formula (36), R^{a} may be hydrogen, deuterium, fluorine, cyano, or substituted or unsubstituted C₁₋₁₀ alkyl. Preferably, R^{a} may be hydrogen, fluorine, or substituted or unsubstituted C₁₋₅ alkyl, typically hydrogen or methyl.

In Formula (36), L⁷ may be a single bond or one or more of substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₃₋₃₀ heteroarylalkyl, or —C(O)—O—.

In Formula (36), R¹⁰⁹ may be —C(O)—OH.

Non-limiting examples of repeating units of Formula (36) may include:

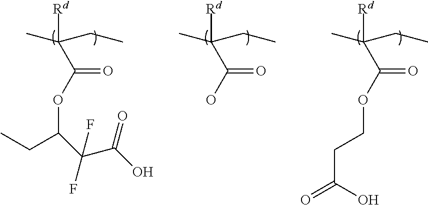

wherein R^{d} may be hydrogen, deuterium, fluorine, cyano, or substituted or unsubstituted C₁₋₁₀ alkyl. Preferably, R^{d} may be hydrogen, fluorine, or substituted or unsubstituted C₁₋₅ alkyl, typically methyl.

The repeating unit including an acid group typically may be present in an amount from 1 to 20 mol %, more typically from 5 to 20 mol %, and still more typically from 5 to 10 mol %, based on total repeating units of the polymer. The repeating units including a hydroxyaryl group typically may be present in the polymer in an amount from 1 to 20 mol %, more typically from 5 to 20 mol %, and still more typically from 5 to 10 mol %, based on total repeating units of the polymer.

Non-limiting exemplary polymers of the present invention include one or more of the following:

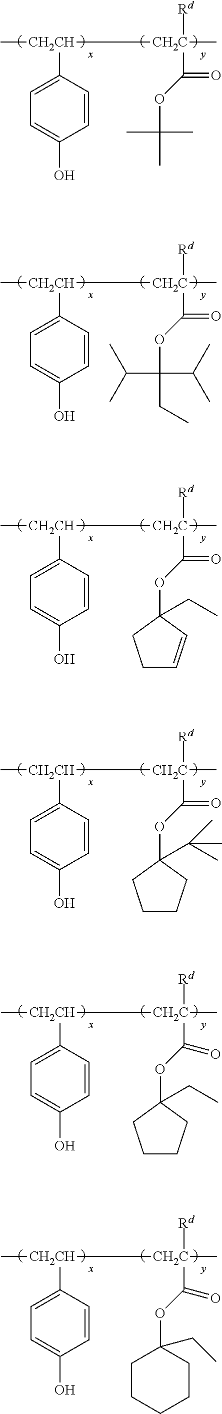

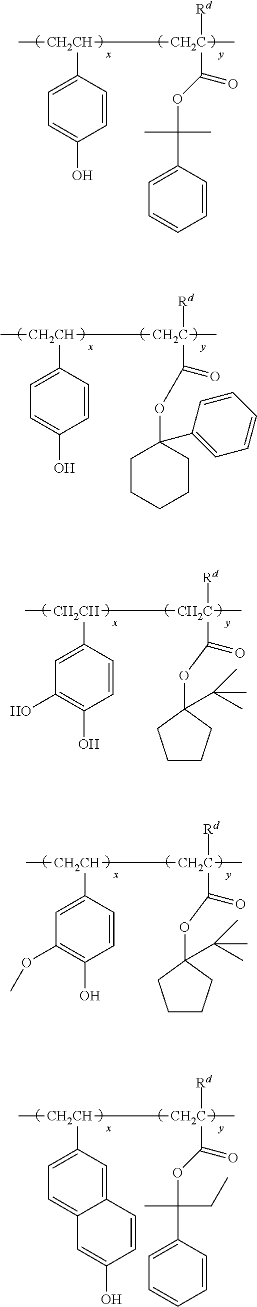

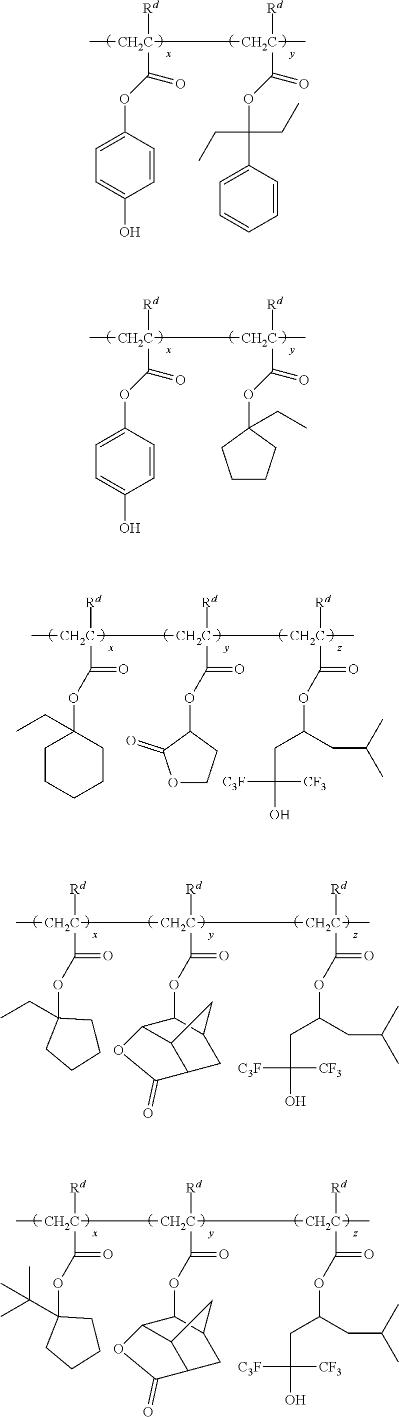

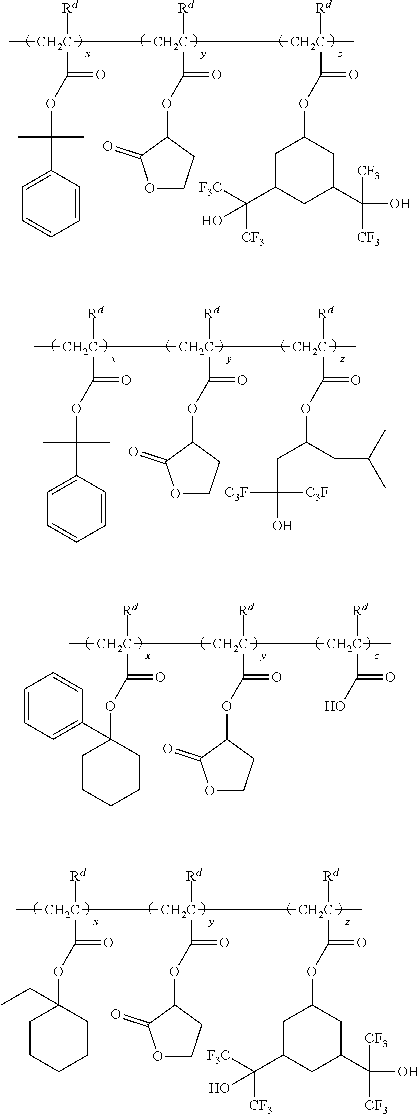

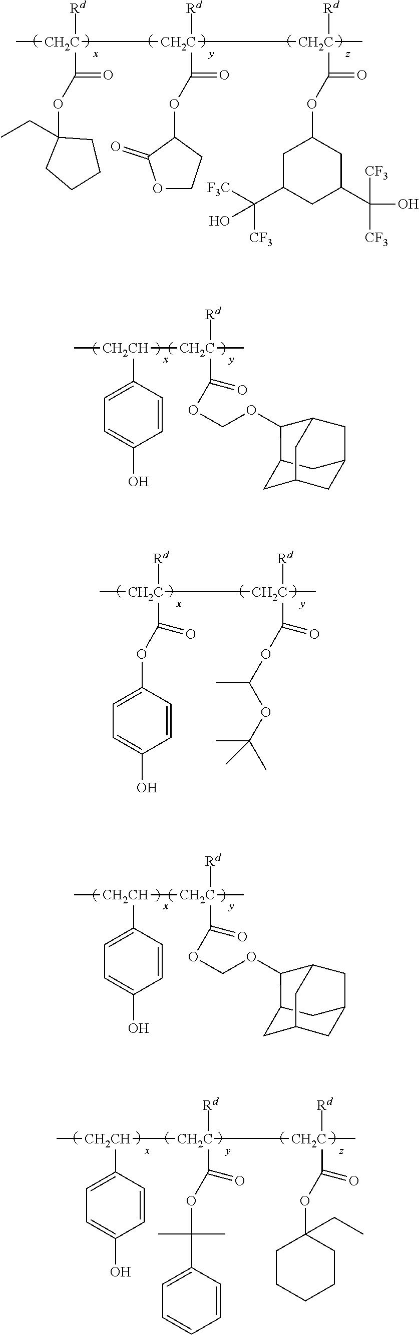

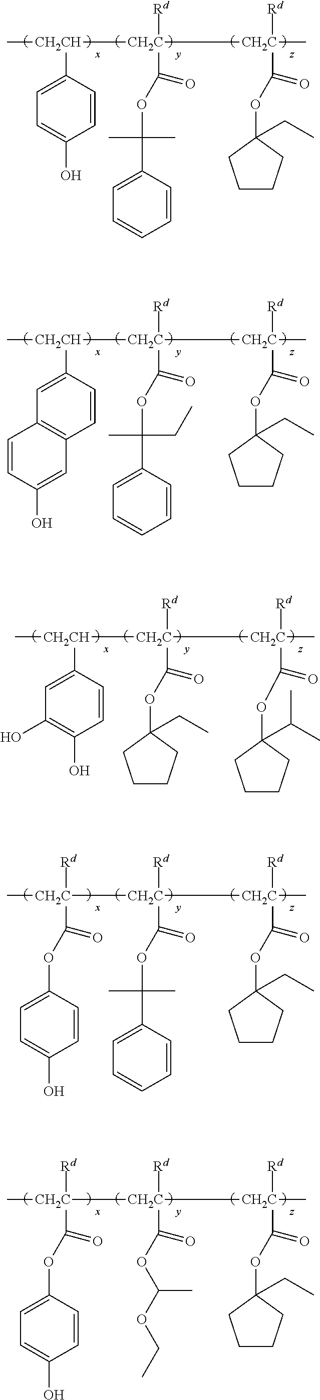

wherein each of x, y and z is a molar fraction of an associated repeating unit, wherein the sum of the molar fractions for each polymer adds up to 1, and wherein each R^{d} is independently hydrogen, deuterium, halogen, substituted or unsubstituted C₁₋₆ alkyl, or substituted or unsubstituted C₃₋₆ cycloalkyl.

The polymer typically has a weight average molecular weight (M_{w}) from 1,000 to 50,000 Dalton (Da), preferably from 2,000 to 30,000 Da, more preferably 3,000 to 20,000 Da, and still more preferably from 4,000 to 15,000 Da. The polydispersity index (PDI) of the first polymer, which is the ratio of M_{w} to number average molecular weight (Mₙ) is typically from 1.1 to 3, and more typically from 1.1 to 2. Molecular weight values are determined by gel permeation chromatography (GPC) using polystyrene standards.

In the compositions of the invention, the polymer is typically present in the composition in an amount from 10 to 99.9 wt %, typically from 25 to 99 wt %, and more typically from 50 to 95 wt %, based on total solids of the composition. It will be understood that total solids includes the polymer(s), PAGs, and other non-solvent components.

The polymers may be prepared using any suitable method(s) in the art. For example, one or more monomers corresponding to the repeating units described herein may be combined, or fed separately, using suitable solvent(s) and initiator, and polymerized in a reactor. For example, the polymer may be obtained by polymerization of the respective monomers under any suitable conditions, such as by heating at an effective temperature, irradiation with actinic radiation at an effective wavelength, or a combination thereof.

The composition also includes a photoacid generator (PAG). The PAG may be in ionic or non-ionic form. The PAG may be in polymeric or non-polymeric form. In polymeric form, the PAG may be present as a moiety in a repeating unit of a polymer that is derived from a polymerizable PAG monomer.

In some embodiments, the composition may include two or more different photoacid generator compounds. In some embodiments, when the photoresist compound includes two or more different photoacid generator compounds, the non-polymeric electron acceptor compound has a greater electron affinity than an electron affinity of each of the two or more photoacid generator compounds.

Suitable PAG compounds maybe of the formula G⁺A⁻, wherein G⁺ is a electroactive cation and A⁻ is an anion that can generate a photoacid. The electroactive cation is preferably chosen from onium cations, preferably iodonium or sulfonium cations. Particularly suitable anions include those whose conjugated acids have a pKa of from −15 to 10. The anion is typically an organic anion having a sulfonate group or a non-sulfonate-type group, such as sulfonamidate, sulfonimidate, methide, or borate.

In some aspects, the anion of the PAG does not include and is free of —F, —CF₃, or —CF₂— groups. It should be understood that “free of —F, —CF₃, or —CF₂— groups” means that the anion of the PAG excludes groups such as —CH₂CF₃ and —CH₂CF₂CH₃. In still other aspects, the anion of the PAG is free of fluorine (i.e., does not contain a fluorine atom and is not substituted by a fluorine-containing group). In some aspects, the photoacid generator is free of fluorine (i.e., both the photoactive cation and the anion are free of fluorine).

The PAG compound includes an organic cation. For example, the organic cation may be a sulfonium cation or an iodonium cation. In some embodiments, the organic cations may be a sulfonium cation of Formula (37a) or an iodonium cation of Formula (37b):

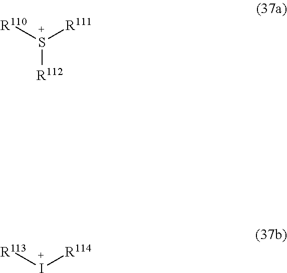

In Formulae (37a) and (37b), R¹¹⁰ to R¹¹⁴ are each independently substituted or unsubstituted C₁₋₂₀ alkyl, substituted or unsubstituted C₃₋₂₀ cycloalkyl, substituted or unsubstituted C₂₋₂₀ alkenyl, substituted or unsubstituted C₆₋₃₀ aryl, substituted or unsubstituted C₆₋₃₀ iodoaryl, substituted or unsubstituted C₃₋₃₀ heteroaryl, substituted or unsubstituted C₇₋₂₀ arylalkyl, or substituted or unsubstituted C₄₋₂₀ heteroarylalkyl, or combinations thereof. Each of R¹¹⁰ to R¹¹⁴ may be either separate or connected to another group of R¹¹⁰ to R¹¹² via a single bond or a divalent linking group to form a ring. R¹¹³ and R¹¹⁴ may be either separate or connected to each other via a single bond or a divalent linking group to form a ring. Each of R¹¹⁰ to R¹¹⁴ optionally may include as part of its structure a divalent linking group. Each of R¹¹⁰ to R¹¹⁴ independently may optionally comprise an acid-labile group chosen, for example, from tertiary alkyl ester groups, secondary or tertiary aryl ester groups, secondary or tertiary ester groups having a combination of alkyl and aryl groups, tertiary alkoxy groups, acetal groups, or ketal groups.

Exemplary sulfonium cations of Formula (37a) include one or more of the following:

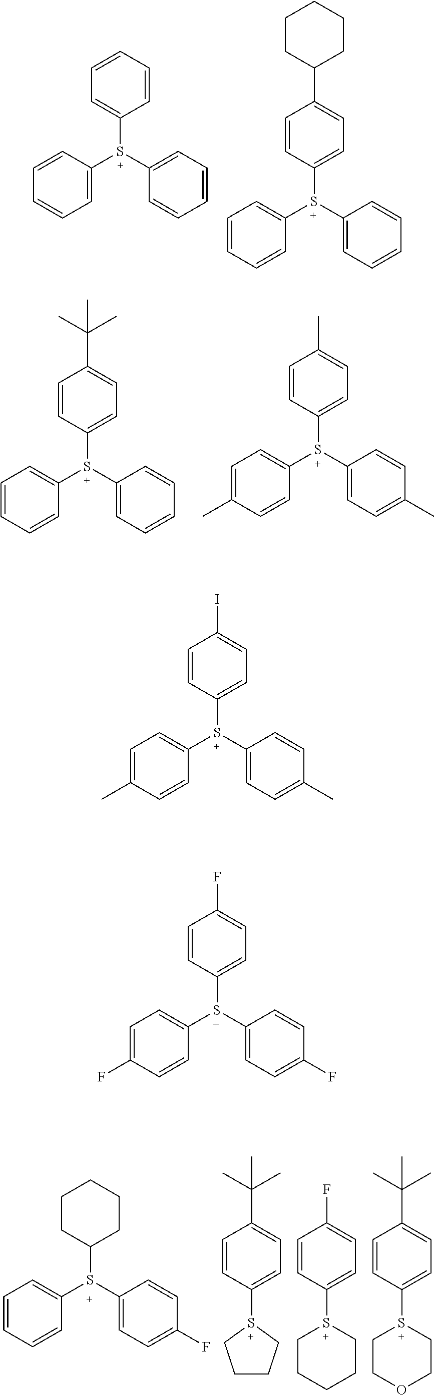

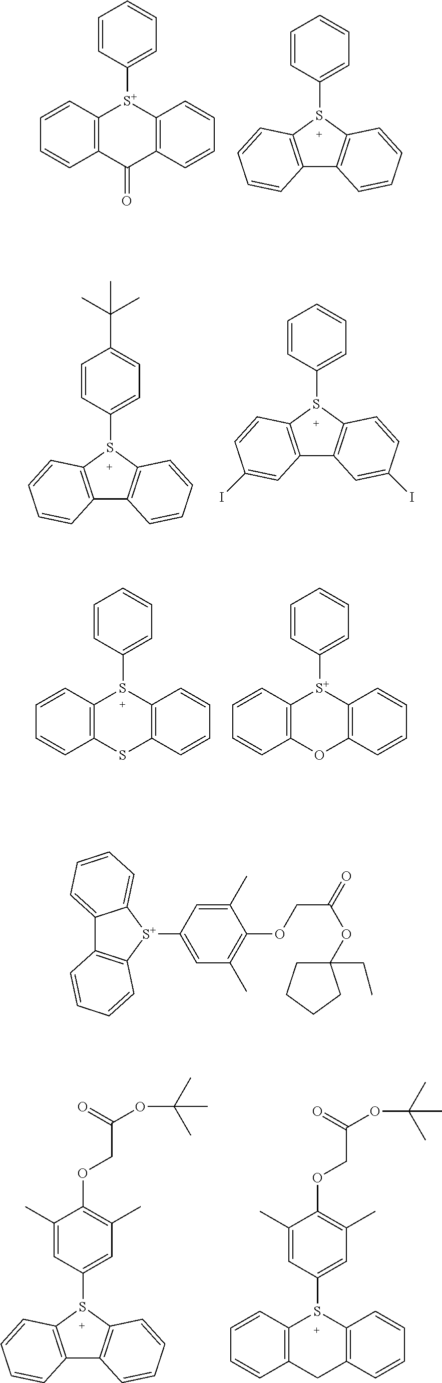

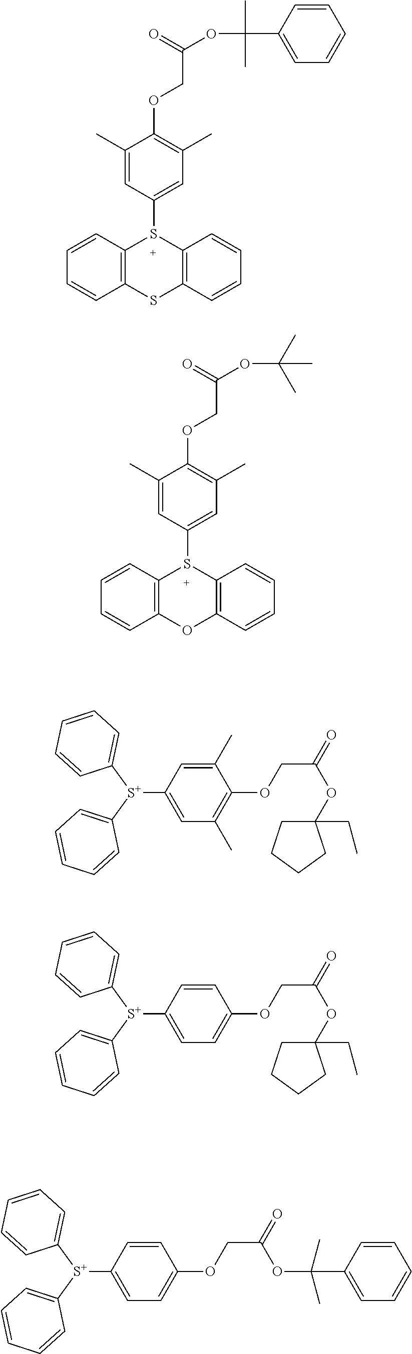

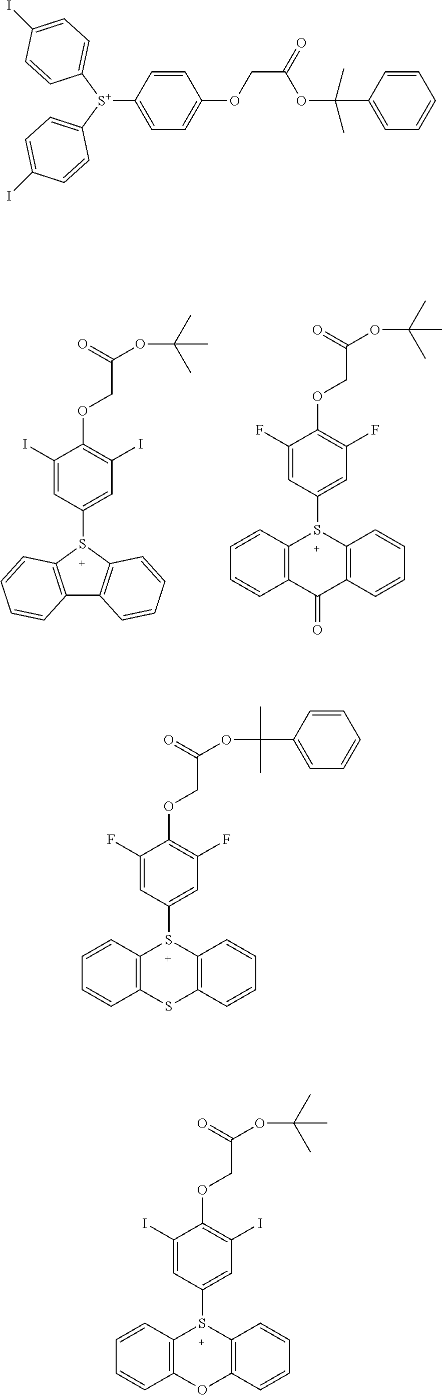

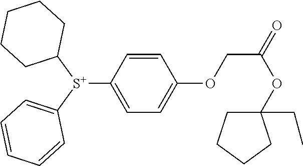 [SMILES: CCC1(OC(=O)COc2ccc([S+](c3ccccc3)C3CCCCC3)cc2)CCCC1]

Exemplary iodonium cations of Formula (37b) may include one or more of the following:

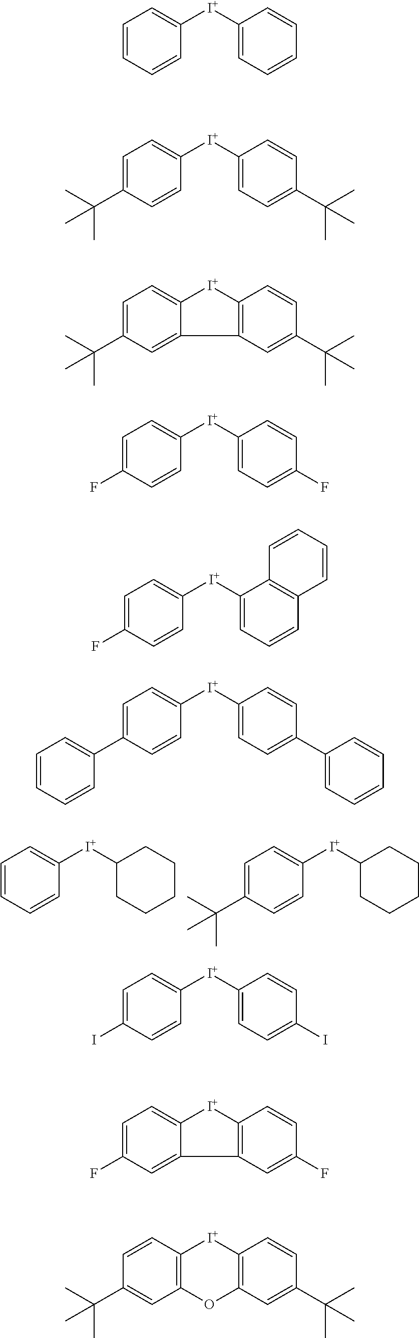

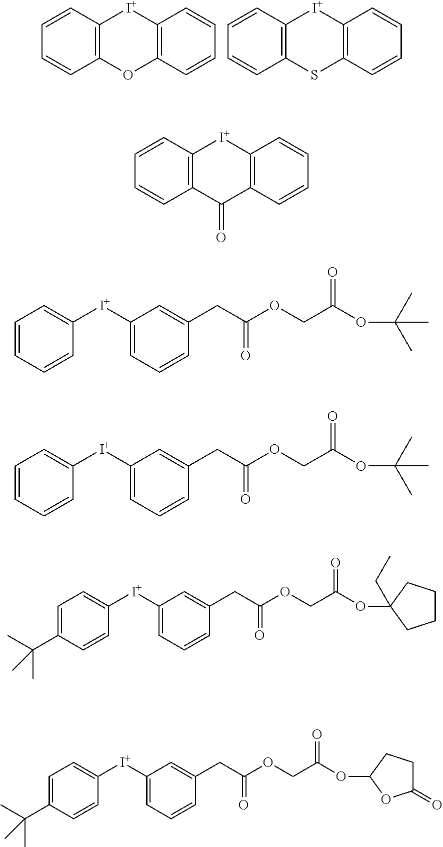

Exemplary organic anions having a sulfonate group include one or more of the following:

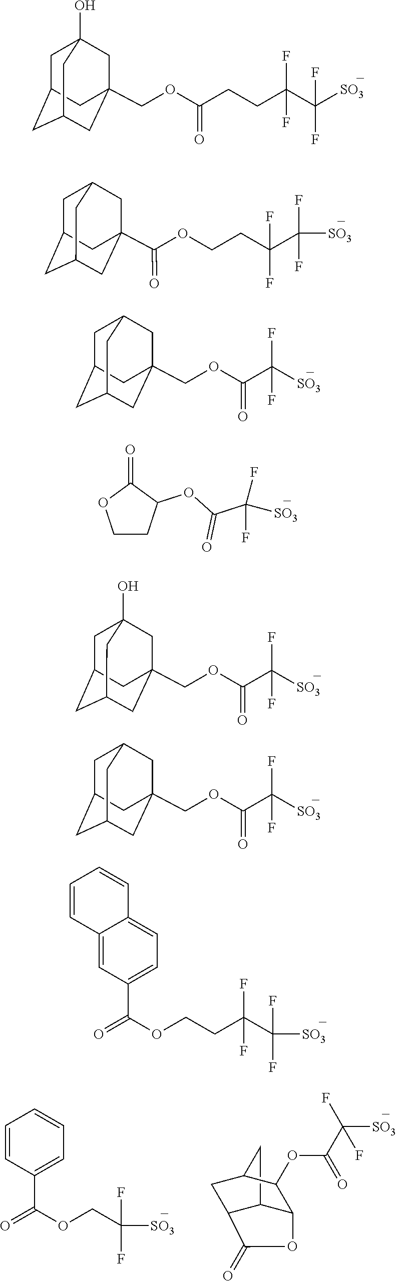

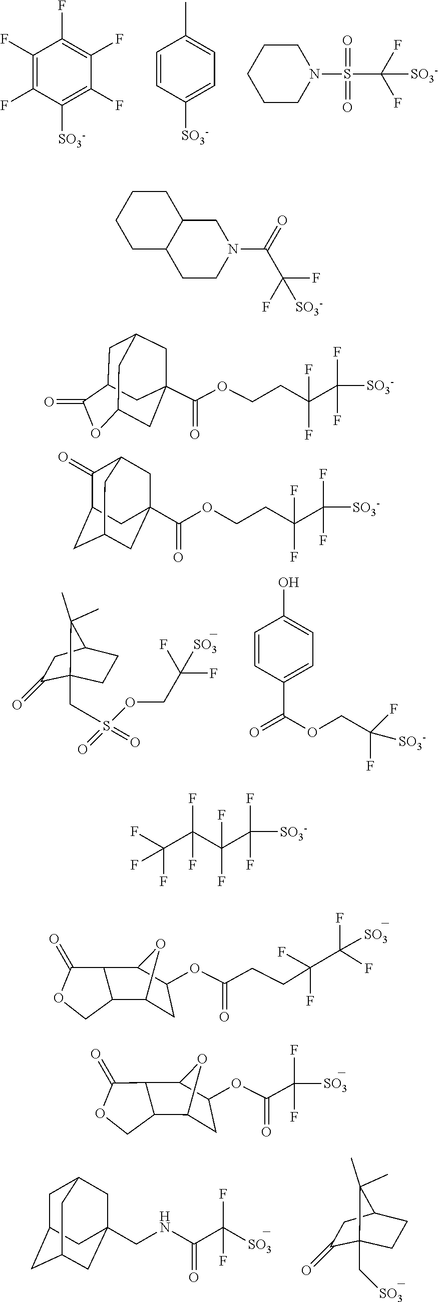

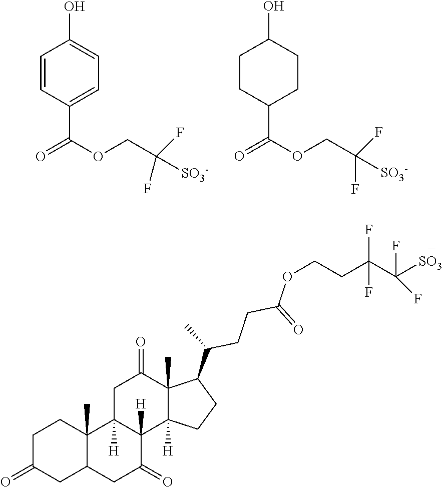

Exemplary non-sulfonated anions include one or more of the following:

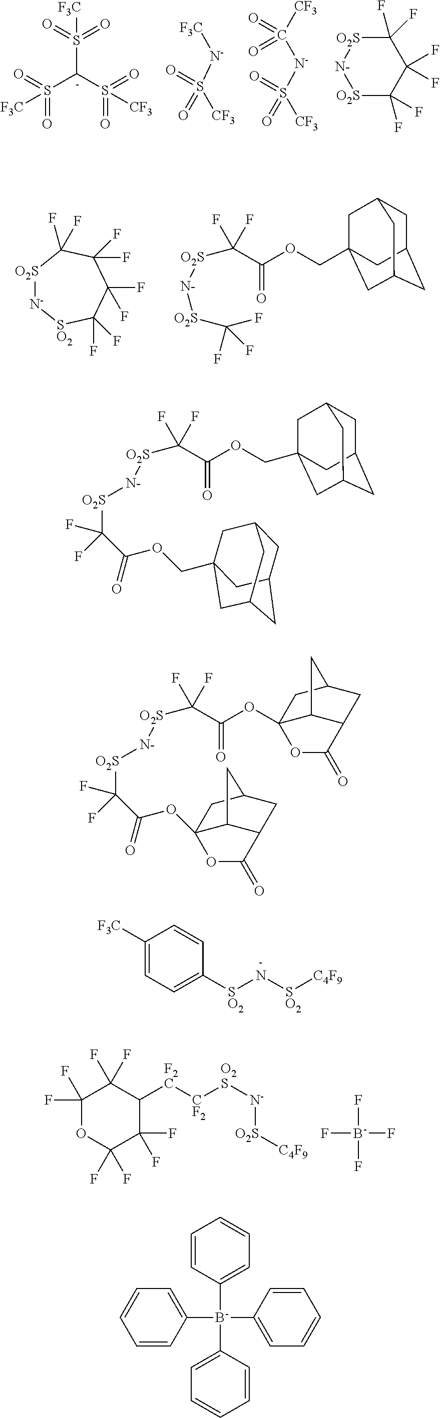

Commonly used onium salts may include, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, and di-t-butyphenyliodonium camphorsulfonate. Other useful PAG compounds are known in the art of chemically amplified photoresists and include, for example: non-ionic sulfonyl compounds, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable photoacid generators are further described in U.S. Pat. Nos. 8,431,325 and 4,189,323.

If the composition comprises a non-polymeric electron acceptor compound and a PAG compound that are in ionic form, the non-polymeric electron acceptor compound can comprise an anion that is structurally the same as an anion of the PAG compound. An anion of the non-polymeric electron acceptor compound can alternatively be structurally different from an anion of the PAG compound. For example, in some embodiments, the photoacid generator compound includes a first anion and the non-polymeric electron acceptor compound includes a second anion, wherein the first anion and the second anion are structurally the same.

Typically, when the composition includes a non-polymeric PAG compound, the PAG compound is present in the composition in an amount of from 0.1 to 55 wt %, more typically 1 to 25 wt %, based on total solids of the composition. When present in polymeric form, the PAG compound is typically included in a polymer in an amount from 1 to 25 mol %, more typically from 1 to 8 mol %, or from 2 to 6 mol %, based on total repeating units in the polymer.

The composition further includes a solvent for dissolving the components of the composition and to facilitate its coating on a substrate. Preferably, the solvent is an organic solvent conventionally used in the manufacture of electronic devices. Suitable solvents include, for example: aliphatic hydrocarbons such as hexane and heptane; aromatic hydrocarbons such as toluene and xylene; halogenated hydrocarbons such as dichloromethane, 1,2-dichloroethane and 1-chlorohexane; alcohols such as methanol, ethanol, 1-propanol, iso-propanol, tert-butanol, 2-methyl-2-butanol, 4-methyl-2-pentanol, and diacetone alcohol (4-hydroxy-4-methyl-2-pentanone) (DAA); propylene glycol monomethyl ether (PGME); ethers such as diethyl ether, tetrahydrofuran, 1,4-dioxane, and anisole; ketones such as acetone, methyl ethyl ketone, methyl iso-butyl ketone, 2-heptanone, and cyclohexanone (CHO); esters such as ethyl acetate, n-butyl acetate, propylene glycol monomethyl ether acetate (PGMEA), ethyl lactate (EL), hydroxyisobutyrate methyl ester (HBM), and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; water; and combinations thereof. Of these, preferred solvents include one or more of PGME, PGMEA, EL, GBL, HBM, CHO, DAA, or a combination thereof.

The total solvent content (i.e., cumulative solvent content for all solvents) in the compositions is typically from 40 to 99 wt %, for example, from 60 to 99 wt %, or from 85 to 99 wt %, based on total solids of the composition. The desired solvent content will depend, for example, on the desired thickness of the coated (photoresist) layer and coating conditions.

In some aspects, the composition may further include a material that comprises one or more base-labile groups (a “base-labile material”) and/or base soluble groups. As referred to herein, a base soluble group are generally polar functional groups that could be ionized in the TMAH type of base and thus soluble during the development stage, while base-labile groups are functional groups that can undergo cleavage reaction to provide the same type of polar groups (e.g., base soluble groups) such as hydroxyl (including phenol), HFA (hexafluoroalcohol), carboxylic acid, sulfonic acid, and the like, in the presence of an aqueous alkaline developer after exposure and post-exposure baking steps. The base-labile group will not react significantly (e.g., will not undergo a bond-breaking reaction) prior to a development step of the composition that comprises the base-labile group. Thus, for instance, a base-labile group will be substantially inert during pre-exposure soft-bake, exposure, and post-exposure bake steps. By “substantially inert” it is meant that ≤5%, typically ≤1%, of the base-labile groups (or moieties) will decompose, cleave, or react during the pre-exposure soft-bake, exposure, and post-exposure bake steps. The base-labile group is reactive under typical photoresist development conditions using, for example, an aqueous alkaline photoresist developer such as a 0.26 normal (N) aqueous solution of tetramethylammonium hydroxide (TMAH). For example, a 0.26 N aqueous solution of TMAH may be used for single puddle development or dynamic development, e.g., where the 0.26 N TMAH developer is dispensed onto an imaged photoresist layer for a suitable time such as 10 to 120 seconds (s). An exemplary base-labile group is an ester group, typically a fluorinated ester group. Preferably, the base-labile material is substantially not miscible with and has a lower surface energy than the first and/or second polymers and other solid components of the composition. When coated on a substrate, the base-labile material can thereby segregate from other solid components of the composition to a top surface of the formed photoresist layer.

In some aspects, the base-labile material may be a polymeric material, also referred to herein as a base-labile polymer, which may include one or more repeating units comprising one or more base-labile groups. For example, the base-labile polymer may comprise a repeating unit comprising 2 or more base-labile groups that are the same or different. The base-labile or base soluble polymer may comprise 1 or more other repeating units such as (meth)acrylate, vinyl aromatic, vinyl ether, vinyl ketone, and/or vinyl ester monomers. A preferred base-labile polymer includes at least one repeating unit comprising two or more base-labile groups, for example a repeating unit comprising 2 or 3 base-labile groups. Another preferred base-labile polymer includes at least one repeating unit comprising one acid decomposable groups.

The base-labile polymer may be prepared using any suitable methods in the art. For example, the base-labile polymer may be obtained by polymerization of the respective monomers under any suitable conditions, such as by heating at an effective temperature, irradiation with actinic radiation at an effective wavelength, or a combination thereof. Additionally, or alternatively, one or more base-labile groups may be grafted onto the backbone of a polymer using suitable methods.

In some aspects, the base-labile material is a single molecule comprising one more base-labile ester groups, preferably one or more fluorinated ester groups. The base-labile materials that are single molecules typically have a M_{w} in the range from 50 to 1,500 Da.

When present, the base-labile material and/or the base soluble material is typically present in the compositions in an amount of from 0.01 to 10 wt %, typically from 1 to 5 wt %, based on total solids of the composition.

Additionally, the compositions may further include one or more polymers in addition to and different from the polymer as described above. For example, the compositions may include an additional polymer as described above but different in composition. Additionally, or alternatively, the one or more additional polymers may include those well known in the photoresist art, for example, those chosen from polyacrylates, polyvinylethers, polyesters, polynorbornenes, polyacetals, polyethylene glycols, polyamides, polyacrylamides, polyphenols, novolacs, styrenic polymers, polyvinyl alcohols, or combinations thereof.

The composition may further include one or more additional, optional additives. For example, optional additives may include actinic and contrast dyes, anti-striation agents, plasticizers, speed enhancers, sensitizers, photo-decomposable quenchers (PDQ) (and, also known as photo-decomposable bases), basic quenchers, thermal acid generators, surfactants, and the like, or combinations thereof. If present, the optional additives are typically present in the compositions in an amount of from 0.01 to 10 wt %, based on total solids of the composition.

PDQs generate a weak acid upon irradiation. The acid generated from a photo-decomposable quencher is not strong enough to react rapidly with acid-labile groups that are present in the resist matrix. Exemplary photo-decomposable quenchers include, for example, photo-decomposable cations, and preferably those also useful for preparing strong acid generator compounds, paired with an anion of a weak acid (pKa>1) such as, for example, an anion of a C₁₋₂₀ carboxylic acid or C₁₋₂₀ sulfonic acid. Exemplary carboxylic acids include formic acid, acetic acid, propionic acid, tartaric acid, succinic acid, cyclohexanecarboxylic acid, benzoic acid, salicylic acid, and the like. Exemplary sulfonic acids include p-toluene sulfonic acid, camphor sulfonic acid and the like. In a preferred embodiment, the photo-decomposable quencher is a photo-decomposable organic zwitterion compound such as diphenyliodonium-2-carboxylate. When a PDQ is included in the composition, the PDQ has a lower electron affinity than the electron affinity of the non-polymeric electron acceptor compound.

The PDQ may be in non-polymeric or polymer-bound form. The polymerized units containing the photo-decomposable quencher are typically present in an amount from 0.1 to 30 mole %, preferably from 1 to 10 mole % and more preferably from 1 to 2 mole %, based on total repeating units of the polymer.

Exemplary basic quenchers include, for example, linear aliphatic amines such as tributylamine, trioctylamine, triisopropanolamine, tetrakis(2-hydroxypropyl)ethylenediamine:n-tert-butyldiethanolamine, tris(2-acetoxy-ethyl) amine, 2,2′,2″,2′″-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N¹,N¹,N³,N³-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

The basic quenchers may be in non-polymeric or polymer-bound form. When in polymeric form, the quencher may be present in repeating units of the polymer. The repeating units containing the quencher are typically present in an amount of from 0.1 to 30 mole %, preferably from 1 to 10 mole % and more preferably from 1 to 2 mole %, based on total repeating units of the polymer.

Exemplary surfactants include fluorinated and non-fluorinated surfactants and can be ionic or non-ionic, with non-ionic surfactants being preferable. Exemplary fluorinated non-ionic surfactants include perfluoro C₄ surfactants such as FC-4430 and FC-4432 surfactants, available from 3M Corporation; and fluorodiols such as POLYFOX PF-636, PF-6320, PF-656, and PF-6520 fluorosurfactants from Omnova. In an aspect, the composition further includes a surfactant polymer including a fluorine-containing repeating unit.

Patterning methods using the compositions of the invention will now be described. Suitable substrates on which the compositions can be coated include electronic device substrates. A wide variety of electronic device substrates may be used in the present invention, such as: semiconductor wafers; polycrystalline silicon substrates; packaging substrates such as multichip modules; flat panel display substrates; substrates for light emitting diodes (LEDs) including organic light emitting diodes (OLEDs); and the like, with semiconductor wafers being typical. Such substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. Suitable substrates may be in the form of wafers such as those used in the manufacture of integrated circuits, optical sensors, flat panel displays, integrated optical circuits, and LEDs. Such substrates may be any suitable size. Typical wafer substrate diameters are 200 to 300 millimeters (mm), although wafers having smaller and larger diameters may be suitably employed according to the present invention. The substrates may include one or more layers or structures which may optionally include active or operable portions of devices being formed.

Typically, one or more lithographic layers such as a hardmask layer, for example, a spin-on-carbon (SOC), amorphous carbon, or metal hardmask layer, a CVD layer such as a silicon nitride (SiN), a silicon oxide (SiO), or silicon oxynitride (SiON) layer, an organic or inorganic underlayer, or combinations thereof, are provided on an upper surface of the substrate prior to coating a composition of the present invention. Such layers, together with an overcoated photoresist layer, form a lithographic material stack.

Optionally, a layer of an adhesion promoter may be applied to the substrate surface prior to coating the compositions. If an adhesion promoter is desired, any suitable adhesion promoter for polymer films may be used, such as silanes, typically organosilanes such as trimethoxyvinylsilane, triethoxyvinylsilane, hexamethyldisilazane, or an aminosilane coupler such as gamma-aminopropyltriethoxysilane. Particularly suitable adhesion promoters include those sold under the AP™ 3000, AP™ 8000, and AP™ 9000S designations, available from DuPont Electronics & Industrial (Marlborough, Massachusetts).

The composition may be coated on the substrate by any suitable method, including spin coating, spray coating, dip coating, doctor blading, or the like. For example, applying the layer of photoresist may be accomplished by spin coating the photoresist in solvent using a coating track, in which the photoresist is dispensed on a spinning wafer. During dispensing, the wafer is typically spun at a speed of up to 4,000 rotations per minute (rpm), for example, from 200 to 3,000 rpm, for example, from 1,000 to 2,500 rpm, for a period from 15 to 120 seconds to obtain a layer of the composition on the substrate. It will be appreciated by those skilled in the art that the thickness of the coated layer may be adjusted by changing the spin speed and/or the total solids of the composition. A EUV (photoresist) composition layer formed from the compositions of the invention typically has a dried layer thickness from 5 nm to 100 nm, preferably from greater than 10 nm to 80 nm, more preferably from 20 nm to 70 nm. An E-beam resist composition layer from the composition of the invention typically has a dried layer thickness from 50 nm to 3 μm, preferably from greater than 70 nm to 1 μm, more preferably from 100 nm to 500 nm.

The composition is typically next soft-baked to minimize the solvent content in the layer, thereby forming a tack-free coating and improving adhesion of the layer to the substrate. The soft bake is performed, for example, on a hotplate or in an oven, with a hotplate being typical. The soft bake temperature and time will depend, for example, on the composition and thickness. The soft bake temperature is typically from 80 to 170° C., and more typically from 90 to 150° C. The soft bake time is typically from 10 seconds to 20 minutes, more typically from 1 to 10 minutes, and still more typically from 1 to 2 minutes. The heating time can be readily determined by one of ordinary skill in the art based on the ingredients of the composition.

The photoresist layer or E-beam resist layer is next pattern-wise exposed to activating radiation to create a difference in solubility between exposed and unexposed regions. Reference herein to exposing a photoresist composition to radiation that is activating for the composition indicates that the radiation can form a latent image in the photoresist composition. The exposure is typically conducted through a patterned photomask that has optically transparent and optically opaque regions corresponding to regions of the resist layer to be exposed and unexposed, respectively. Such exposure may, alternatively, be conducted without a photomask in a direct writing method, typically used for e-beam lithography. The exposure is conducted with activating radiation such as 13.5 nm (EUV) or shorter wavelength, or by electron-beam (e-beam). The exposure energy is typically from 1 to 200 millijoules per square centimeter (mJ/cm²), preferably from 5 to 100 mJ/cm², and more preferably from 20 to 50 mJ/cm², dependent upon the exposure tool and components of the photoresist composition.

Following exposure of the photoresist layer, a post-exposure bake (PEB) of the exposed photoresist layer is performed. The PEB can be conducted, for example, on a hotplate or in an oven, with a hotplate being typical. Conditions for the PEB will depend, for example, on the photoresist composition and layer thickness. The PEB is typically conducted at a temperature from 70 to 150° C., preferably from 75 to 120° C., and a time from 30 to 120 seconds. A latent image defined by the polarity-switched (exposed regions) and unswitched regions (unexposed regions) is formed in the photoresist.

The exposed photoresist layer is then developed with a suitable developer to selectively remove those regions of the layer that are soluble in the developer while the remaining insoluble regions form the resulting photoresist pattern relief image. In the case of a positive-tone development (PTD) process, the exposed regions of the photoresist layer are removed during development and unexposed regions remain. Conversely, in a negative-tone development (NTD) process, the exposed regions of the photoresist layer remain, and unexposed regions are removed during development. Application of the developer may be accomplished by any suitable method such as described above with respect to application of the composition, with spin coating being typical. The development time is for a period effective to remove the soluble regions of the photoresist, with a time of from 5 to 60 seconds being typical. Development is typically conducted at room temperature.

Suitable developers for a PTD process include aqueous base developers, for example, quaternary ammonium hydroxide solutions such as TMAH, preferably 0.26 N TMAH, tetraethylammonium hydroxide, tetrabutylammonium hydroxide, sodium hydroxide, potassium hydroxide, sodium carbonate, potassium carbonate, and the like. Suitable developers for an NTD process are organic solvent-based, meaning the cumulative content of organic solvents in the developer is 50 wt % or more, typically 95 wt % or more, 98 wt % or more, or 100 wt %, based on total weight of the developer. Suitable organic solvents for the NTD developer include, for example, those chosen from ketones, esters, ethers, hydrocarbons, and mixtures thereof. The developer is typically 2-heptanone or n-butyl acetate.

A coated substrate may be formed from the compositions of the invention. Such a coated substrate includes: (a) a substrate having one or more layers to be patterned on a surface thereof; and (b) a layer of the composition over the one or more layers to be patterned.

The photoresist pattern may be used, for example, as an etch mask, thereby allowing the pattern to be transferred to one or more sequentially underlying layers by known etching techniques, typically by dry-etching such as reactive ion etching. The photoresist pattern may, for example, be used for pattern transfer to an underlying hardmask layer which, in turn, is used as an etch mask for pattern transfer to one or more layers below the hardmask layer. If the photoresist pattern is not consumed during pattern transfer, it may be removed from the substrate by known techniques, for example, oxygen plasma ashing. The compositions may, when used in one or more such patterning processes, be used to fabricate semiconductor devices such as memory devices, processor chips (CPUs), graphics chips, optoelectronic chips, LEDs, OLEDs, as well as other electronic devices.

The invention is further illustrated by the following non-limiting examples.

### Examples

### Electron Affinity and LUMO Energy Calculations

The calculated electron affinity (EA) energy of the PAG cation triphenylsulfonium and non-polymeric electron acceptor compounds from the invention are collated in Table 1. For the calculation execution, Density Functional Theory (DFT) at the B3LYP level, employing the 6-31+G(d,p) basis set was utilized. The modeling was performed for each molecule in solution by using the polarizable continuum (PC) model with propylene carbonate as a solvent. Vibration frequency analysis was used to confirm global minimum energy geometry. The computed energies of the optimized structures were used to calculate the adiabatic electron affinity. The electron affinity was computed as the energy difference between neutral form and the form produced upon the addition of one electron, which was the corresponding anion-radical form. For positively charge species, such as a sulfonium cation having a charge of +1, the electron affinity was computed as the energy difference between sulfonium with +1 charge and the radical form that was produced upon the addition of one electron.

Quantum chemical calculations were used to calculate the lowest unoccupied molecular orbital (LUMO) energies. DFT calculations were used according to the Gaussian 16 software package with the B3LYP functional and 6-31+G(d,p) basis set. The modeling was performed for each molecule in solution by using the polarizable continuum (PC) model with propylene carbonate as a solvent. Vibration frequency analysis was used to confirm global minimum energy geometry. Once optimized, the DFT output file containing the molecular orbital energies was obtained. The lowest unoccupied molecular orbital (LUMO) energy was extracted from the output.

TABLE 1

| | | LUMO |
|---|---|---|
| Electron acceptor | EA | energy |
| compound | (eV) | (eV) |
| EA1 | 4.0 | −3.7 |
| EA2 | 3.5 | −3.1 |
| EA3 | 4.8 | −4.5 |
| EA4 | 4.9 | −4.6 |
| EA5 | 4.2 | −3.9 |
| EA6 | 3.9 | −3.6 |
| EA7 | 4.1 | −3.8 |
| EA8 | 3.9 | −3.6 |
| EA9 | 4.1 | −3.7 |
| EA10 | 5.3 | −5.0 |
| EA11 | 4.7 | −4.4 |
| EA12 (TPS) | 3.2 | −2.0 |

As can be seen in Table 1, each of the inventive non-polymeric electron acceptor compounds EA1 to EA11 exhibited higher EA compared to the cation TPS (EA12). Similarly, as can be seen in Table 1, each of inventive electron acceptor compounds EA1 to EA11 exhibited lower LUMO energy levels as compared to the cation TPS (EA12).

The structures of the electron acceptor compounds EA1 to EA11 and the cation TPS (EA12) were as follows:

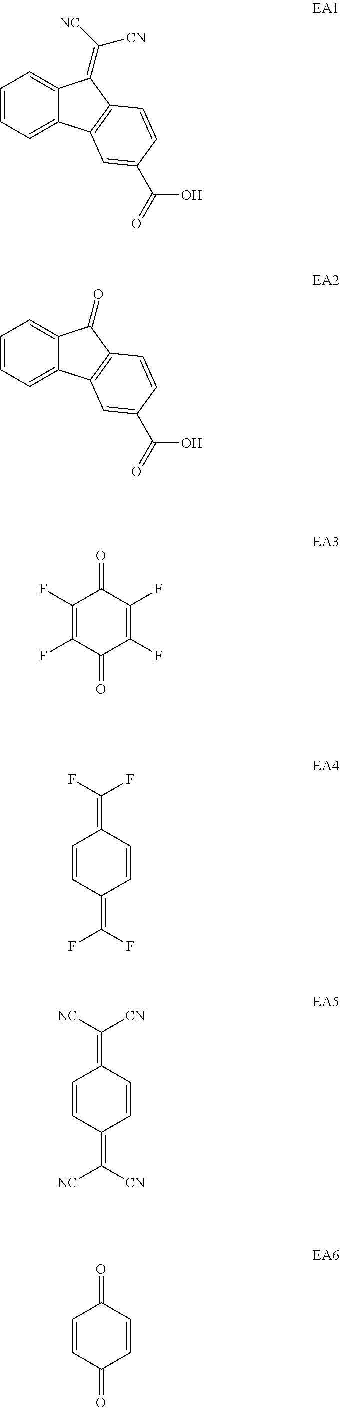 [SMILES: N#CC(C#N)=C1c2ccccc2-c2cc(C(=O)O)ccc21 ; O=C(O)c1ccc2c(c1)-c1ccccc1C2=O ; O=C1C(F)=C(F)C(=O)C(F)=C1F ; FC(F)=c1ccc(=C(F)F)cc1 ; N#CC(C#N)=c1ccc(=C(C#N)C#N)cc1 ; O=C1C=CC(=O)C=C1]

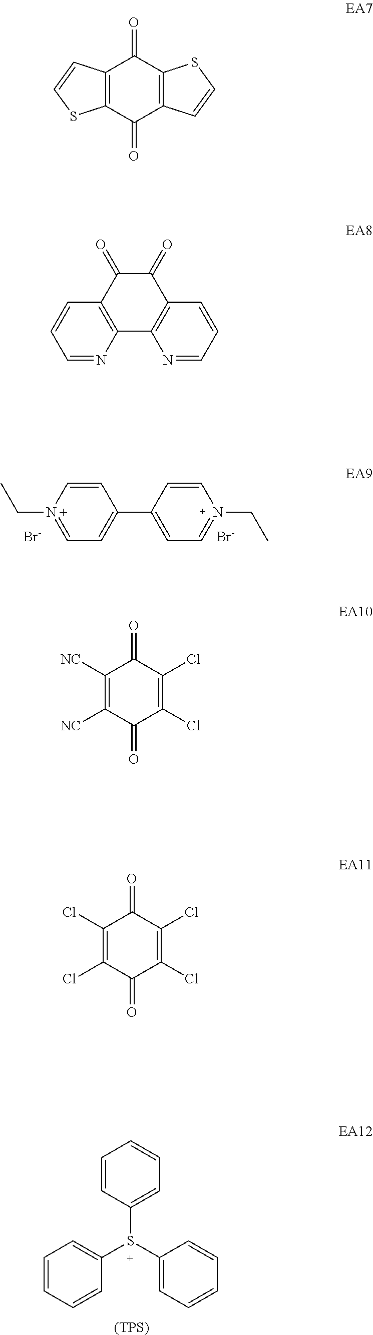

### Reduction Potential Measurement

Et₂-Vio-Br₂ (EA9) was purchased from Aldrich and used as received. Cyclic voltammetry measurement were done as described below.

“Reduction potential” represents the affinity of a material to accept an electron(s), and generally correlated well with electron affinity. It can be measured by cyclic voltammetry, by measuring the Formal Potential (E^{o′}). Herein, the cyclic voltametric responses were irreversible, such that the E^{o′} could not be directly measured and instead the reduction potentials were estimated by the cathodic peak potentials. Specifically, each of the material was dissolved in acetonitrile (HPLC grade, Sigma-Aldrich) to prepare a 1 mM solution of the testing molecule for the measurement. A 0.1 M solution of tetrabutylammonium perchlorate (>99%, Sigma-Aldrich) was used as a supporting electrolyte. With respect to electrodes, a 4 mm disk Pt disk electrode, coiled Pt wire, and a Ag/AgCl electrode were used as a working electrode, a counter electrode, and a reference electrode, respectively. The solution was purged with N₂ gas for 5-10 minutes prior to the electrochemical measurement to displace dissolved O₂. The measurement was conducted at approximately 23.5° C. (temperature was not controlled for these experiments/they were done at room temperature). The scanning rate was 50 mV/s.

The comparison of the dibromo viologen compound Et₂-Vio-Br₂ (EA9) with TPS cation and diphenyliodonium cations are provided in Table 2:

TABLE 2

| Molecule | Structure | E_{red, 1} |
|---|---|---|
| EA9 Br₂ | 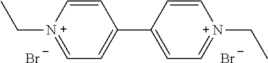 [SMILES: CC[n+]1ccc(-c2cc[n+](CC)cc2)cc1 ; [Br-] ; [Br-]] | −0.41 V |
| EA12 PFBuS | 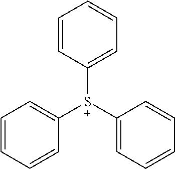 [SMILES: c1ccc([S+](c2ccccc2)c2ccccc2)cc1] | −1.50 V |
| | 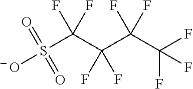 [SMILES: O=S(=O)([O-])C(F)(F)C(F)(F)C(F)(F)C(F)(F)F] | |
| Di-tert-butylphenyl iodonium PFBuS | 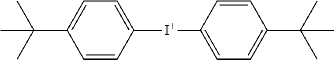 [SMILES: CC(C)(C)c1ccc([I+]c2ccc(C(C)(C)C)cc2)cc1] | −0.81 V |
| | 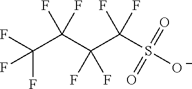 [SMILES: O=S(=O)([O-])C(F)(F)C(F)(F)C(F)(F)C(F)(F)F] | |

As can be seen in Table 2, the inventive electron acceptor compound EA9 (i.e., the cation portion thereof) has a higher reduction potential that the sulfonium cation and the iodonium cation.

### Synthesis of Et₂Vio Di-PFBuS (A1)

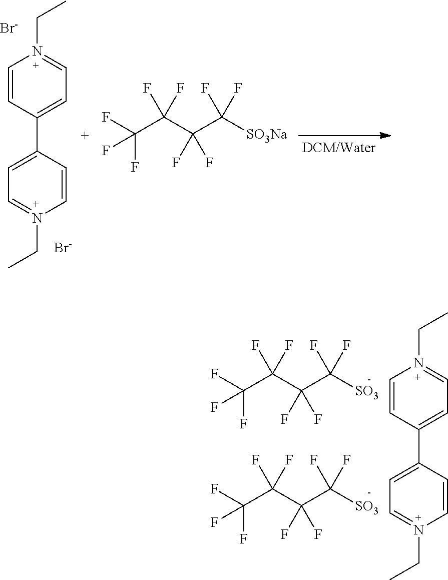

The synthetic reactions were performed under a nitrogen atmosphere. All chemicals were used as received from commercial suppliers and used without further purification. Proton nuclear magnetic resonance (1H-NMR) spectra for all compounds were obtained either on a 500-megahertz (MHz) NMR spectrometer. The chemical shifts are reported in 6 (parts per million, ppm) relative to an internal tetramethylsilane standard. Multiplicities are indicated by singlet (s), doublet (d), triplet (t), quartet (q), multiplet (m), doublet of doublets (dd), doublet of triplets (dt), triplet of triplets (tt), or broad singlet (br).

1,1′-Diethyl-[4,4′-bipyridine]-1,1′-diium bromide (3.74 g), sodium nonafluoro-1-butanesulfonate (6.44 g), dichloromethane (DCM) (50 mL), and water (50 mL) were added to round bottom flask, and stirred at room temperature for 1 day. White solid was precipitated out. The mixture was filtered, and the solid was washed with water for 3 times and DCM for 3 times. The solid was dried in vacuum oven for 2 days to obtain product as white solid (6.12 g, 75% yield). ¹H-NMR (500 MHz, acetone-d₆) d: 9.49 (d, 4H), 8.89 (d, 4H), 5.04 (q, 4H), 1.82 (t, 6H).

### Photoresist Compositions

The chemical structures of the polymer (MP1); quencher (Q1); photoacid generators PAG1, PAG2, and PAG3; and electron acceptor compounds A1, A2, A3, and A4 that were used in the working examples and comparative examples are shown below:

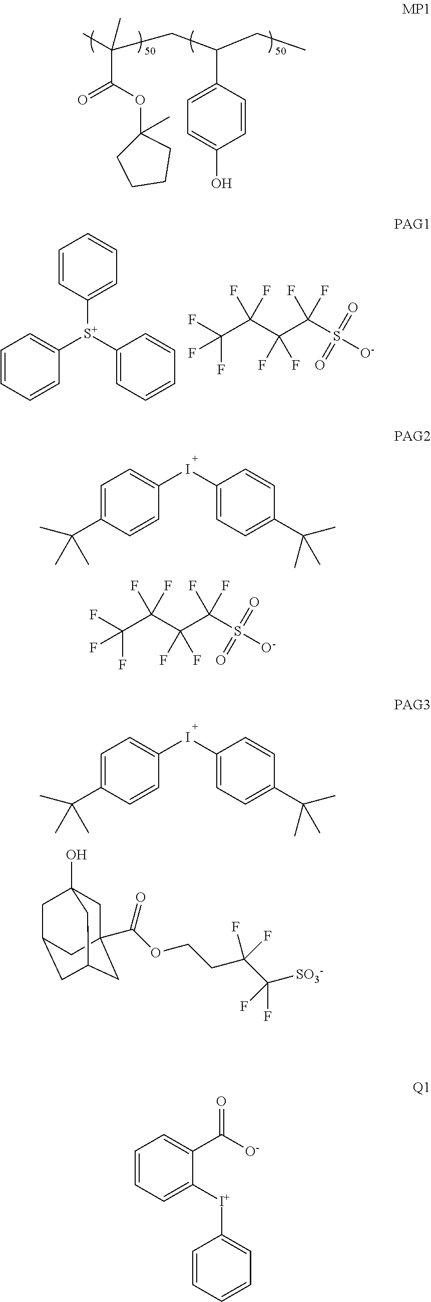

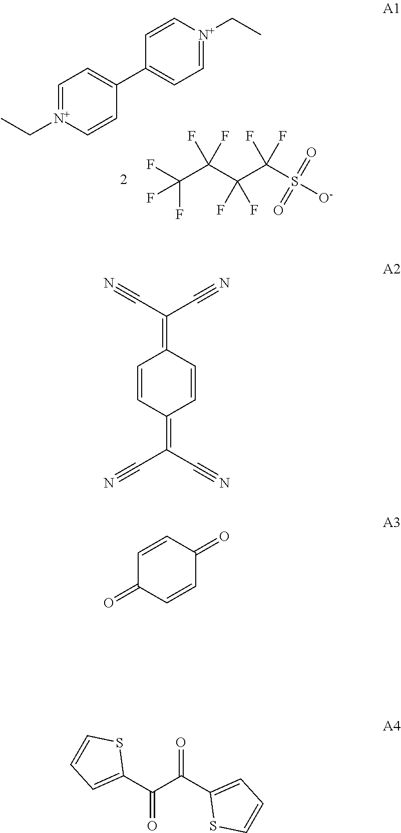 [SMILES: CC[n+]1ccc(-c2cc[n+](CC)cc2)cc1 ; O=S(=O)([O-])C(F)(F)C(F)(F)C(F)(F)C(F)(F)F ; N#CC(C#N)=c1ccc(=C(C#N)C#N)cc1 ; O=C1C=CC(=O)C=C1 ; O=C(C(=O)c1cccs1)c1cccs1]

Photoresist compositions were prepared by dissolving solid components in solvents using the materials and amounts indicated in Table 3, where the amounts are listed in grams. The total solids content for the photoresist compositions was 2.27 wt %. The solvent blends included propylene glycol methyl ether acetate (S1), propylene glycol methyl ether (S2), methyl-2-hydroxyisobutyrate (S3), ethyl lactate (S4), and/or diacetone alcohol (S5). Each solution was filtered four times through 0.01 μm high density polyethylene disk filters and packaged into microclean bottles prior to use.

TABLE 3

| Photoresist | | Photoacid | | Electron | |
|---|---|---|---|---|---|
| Composition | Polymer | generator | Quencher | Acceptor | Solvent(s) |
| PR1 | MP1 | PAG1 | Q1 | — | S1 |
| (comparative) | [1.715] | [0.379] | [0.176] | | [48.865] |
| | | | | | S3 |
| | | | | | [48.865] |
| PR2 | MP1 | PAG1 | Q1 | A1 | S1 |
| | [1.653] | [0.364] | [0.170] | [0.083] | [48.865] |
| | | | | | S3 |
| | | | | | [48.865] |
| PR3 | MP1 | PAG2 | Q1 | — | S1 |
| (comparative) | [1.652] | [0.449] | [0.169] | | [48.865] |
| | | | | | S2 |
| | | | | | [48.865] |
| PR4 | MP1 | PAG2 | Q1 | A1 | S1 |
| | [1.594] | [0.433] | [0.163] | [0.08] | [48.865] |
| | | | | | S2 |
| | | | | | [48.865] |
| PR5 | MP1 | PAG3 | Q1 | — | S1 |
| (comparative) | [1.604] | [0.501] | [0.165] | | [9.773] |
| | | | | | S3 |
| | | | | | [19.546] |
| | | | | | S5 |
| | | | | | [68.411] |
| PR6 | MP1 | PAG3 | Q1 | A2 | S1 |
| | [1.582] | [0.494] | [0.162] | [0.032] | [9.773] |
| | | | | | S3 |
| | | | | | [19.546] |
| | | | | | S5 |
| | | | | | [68.411] |
| PR7 | MP1 | PAG3 | Q1 | A3 | S1 |
| | [1.592] | [0.498] | [0.164] | [0.016] | [9.773] |
| | | | | | S3 |
| | | | | | [19.546] |
| | | | | | S4 |
| | | | | | [68.411] |
| PR8 | MP1 | PAG3 | Q1 | A4 | S1 |
| | [1.582] | [0.494] | [0.162] | [0.032] | [9.773] |
| | | | | | S3 |
| | | | | | [19.546] |
| | | | | | S4 |
| | | | | | [68.411] |

### EUV Lithographic Evaluation

EUV lithography was carried out on 300 mm diameter silicon wafers wherein photoresists were coated onto an underlayer stack (20 nm silicon based underlayer over 60 nm organic underlayer) to a thickness of 60 nm using a post application bake of 110° C. for 60 seconds. Coated wafers were then exposed through a contact hole mask in matrices of varying dose and focus settings on an ASML NXE3400B EUV scanner having numerical aperture of 0.33. Following exposure, the wafers were postexposure baked (PEB) at 100° C. for 60 seconds, developed in CD-26 for 30 seconds, rinsed with deionized water, and spun dry. Critical dimensions (CDs) of imaged holes were measured on a Hitachi CG5000 CD-scanning electron microscope (SEM). Dose to size (E_{size}) was defined as the exposure dose required to print a hole at target CD of 24 nm and pitch of 64 nm, or at target CD of 28 nm and pitch of 44 nm. Local critical dimension uniformity (LCDU) of the holes at or close to target CD was defined as 3 multiplied by the standard deviation (σ) in the hole CDs measured from 20 fields of view (FOV). The pseudo Z-factor is reported below and was determined according to Equation 1:

$$Pseudo Z - factor = ( {E}_{size} ) \times {( LCDU )}^{2} \qquad Equation 1$$

wherein E_{size} is reported in millijoules per square centimeter (mJ/cm²) and LCDU is reported in nanometers (nm). The pseudo Z-factor (Z′-factor) is a modified measure of photoresist performance based on the Z-factor, which is a known parameter indicative of RLS (Resolution, Line Edge Roughness, Sensitivity) photoresist performance (see, e.g., Wallow, T. et al. Proc. SPIE 6921, 69211F, 2008). The pseudo Z-factor was calculated at a constant resolution (CD size).

The EUV lithographic results are provided in Table 4 (24 nm/64 nm pitch contact holes) and Table 5 (28 nm/44 nm pitch contact holes).

TABLE 4

| | | | Pseudo |
|---|---|---|---|
| Photoresist | E_{size} | LCDU | Z- |
| Composition | (mJ/cm²) | (nm) | factor |
| PR1 | 85.4 | 3.11 | 826 |
| (comparative) | | | |
| PR2 | 88.9 | 2.99 | 795 |
| PR5 | 121.6 | 3.23 | 1269 |
| (comparative) | | | |
| PR6 | 119.4 | 2.49 | 740 |
| PR7 | 93.4 | 2.41 | 524 |
| PR8 | 94.3 | 2.48 | 579 |

TABLE 5

| | | | Pseudo |
|---|---|---|---|
| Photoresist | E size | LCDU | Z- |
| Composition | (mJ/cm²) | (nm) | factor |
| PR3 | 96.7 | 2.58 | 644 |
| (comparative) | | | |
| PR4 | 101.2 | 2.44 | 603 |
| PR5 | 128.7 | 2.6 | 870 |
| (comparative) | | | |
| PR6 | 129.9 | 2.54 | 838 |
| PR7 | 105 | 2.34 | 575 |
| PR8 | 107 | 2.42 | 627 |

As demonstrated in Tables 4 and 5, improved lithographic performance was achieved by using a non-polymeric secondary electron acceptor compound with a higher electron affinity than the photoacid generator compound.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A composition, comprising:
an acid-sensitive polymer comprising a first repeating unit derived from a monomer comprising an acid-decomposable group;
a photoacid generator compound;
a non-polymeric electron acceptor compound that has a greater electron affinity than an electron affinity of the photoacid generator compound, wherein the non-polymeric electron acceptor compound does not generate a photoacid, and wherein the non-polymeric electron acceptor compound does not comprise a plurality of diazonaphthoquinone (DNQ) groups; and
a solvent, wherein the solvent is present in the composition in an amount greater than 50 weight percent, based on total weight of the composition,
wherein the composition is a positive-acting EUV photoresist or an electron beam resist.

2. The composition of claim 1, comprising two or more photoacid generator compounds, wherein the non-polymeric electron acceptor compound has a greater electron affinity than an electron affinity of each of the two or more photoacid generator compounds.

3. The composition of claim 1, further comprising a base-labile material, a base soluble material, or a combination thereof.

4. The composition of claim 1, wherein the photoacid generator compound comprises a first anion and the non-polymeric electron acceptor compound comprises a second anion, wherein the first anion and the second anion are structurally the same.

5. The composition of claim 1, wherein the acid-sensitive polymer further comprises a second repeating unit, and wherein the second repeating unit comprises a hydroxyaryl group.

6. The composition of claim 1, wherein the non-polymeric electron acceptor compound comprises a compound represented by one of Formulae (1) to (5): 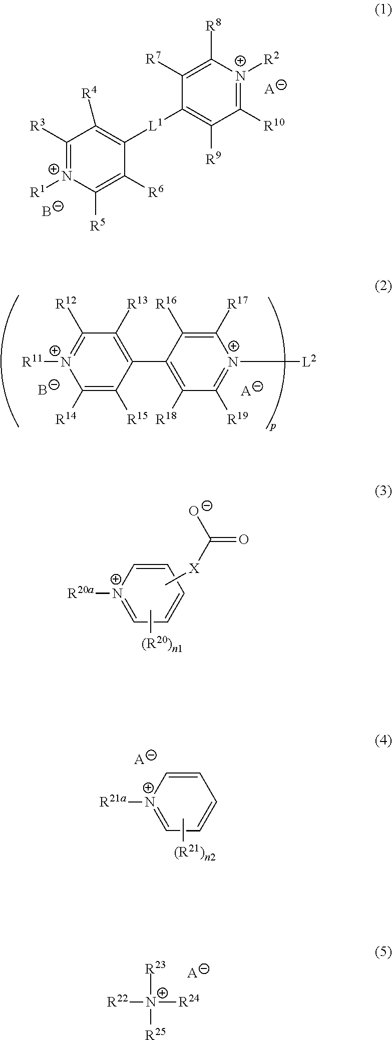
wherein, in Formulae (1) to (5),
R¹ to R²⁵, R^{20a}, and R^{21a} are each independently hydrogen, deuterium, halogen, nitro, amino, cyano, pyridinium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl;
each of R¹ to R²⁵, R^{20a}, and R^{21a} optionally further comprises one or more divalent linking groups as a part of its structure,
adjacent two or more of R¹ to R¹⁰ optionally form a ring with each other via one or more divalent linking groups, adjacent two or more of R¹¹ to R¹⁹ optionally form a ring with each other via one or more divalent linking groups, adjacent two or more R²⁰ optionally form a ring with each other via one or more divalent linking groups, adjacent two or more R²¹ optionally form a ring with each other via one or more divalent linking groups, two or more of R²² to R²⁵ optionally form a ring with each other via one or more divalent linking groups;
L¹ is a single bond or a divalent linking group;
L² is a single bond or a multivalent linking group;
p is an integer from 2 to 6;
n₁ is an integer from 0 to 4;
n₂ is an integer from 0 to 5;
X is a single bond or one or more divalent linking groups; and
A⁻ and B⁻ are each independently an organic anion, wherein A⁻ and B⁻ are optionally joined together to form a divalent organic anion.

7. The composition of claim 1, wherein the non-polymeric electron acceptor compound comprises a compound represented by one of Formula (6) to (26): 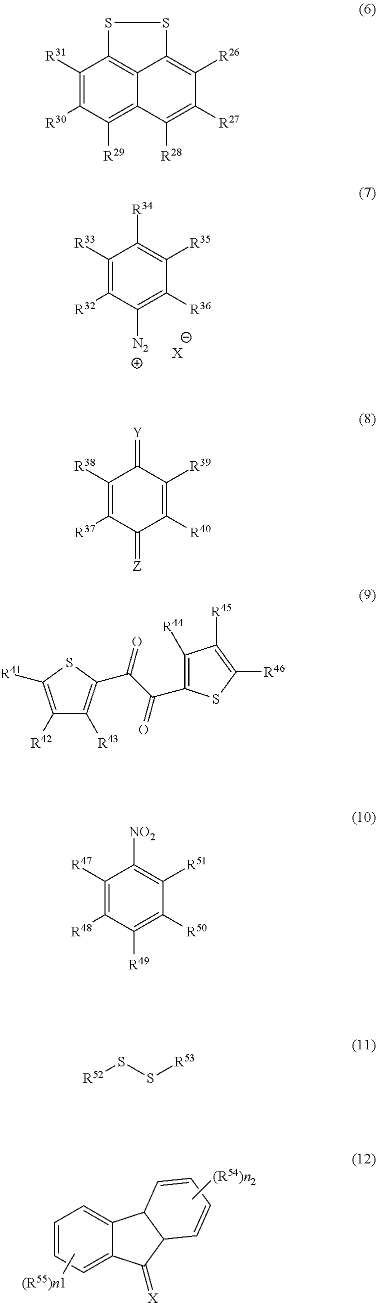 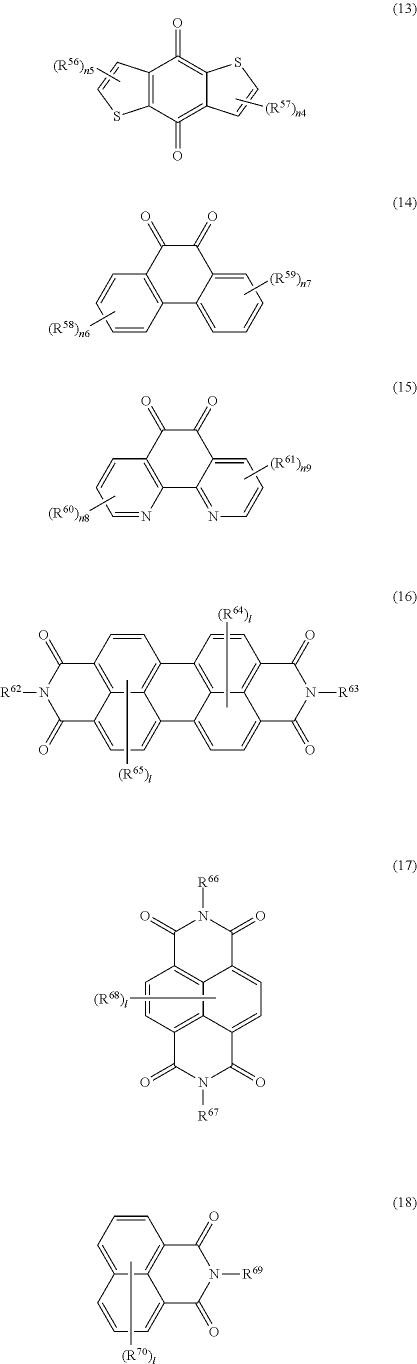 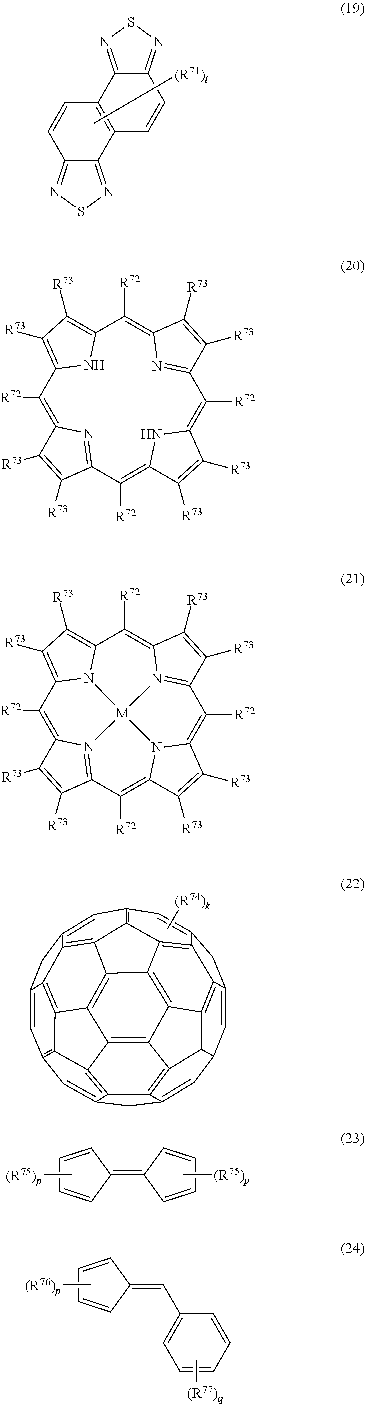 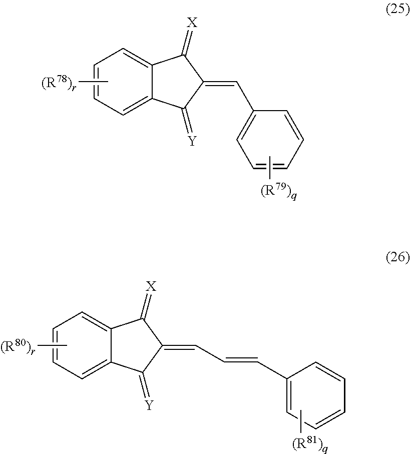
wherein, in Formula (6) to (26),
R²⁶ to R⁸¹ are each independently hydrogen, deuterium, halogen, nitro, amino, cyano, pyridinium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl;
each of R²⁶ to R⁸¹ optionally further comprises one or more divalent linking groups as a part of its structure;
adjacent two or more of R²⁶ to R³¹ optionally form a ring with each other via one or more divalent linking groups; adjacent two or more of R³² to R³⁶ optionally form a ring with each other via one or more divalent linking groups; adjacent two or more of R³⁷ to R⁴⁰ optionally form a ring with each other via one or more divalent linking groups; adjacent two or more of R⁴¹ to R⁴⁶ optionally form a ring with each other via one or more divalent linking groups; adjacent two or more of R⁴⁷ to R⁵¹ optionally form a ring with each other via one or more divalent linking groups; adjacent two or more of R⁵⁴ to R⁵⁵ optionally form a ring with each other via one or more divalent linking groups; adjacent two or more of R⁵⁶ to R⁵⁷ optionally form a ring with each other via one or more divalent linking groups; adjacent two or more of R⁵⁸ to R⁵⁹ optionally form a ring with each other via one or more divalent linking groups; adjacent two or more of R⁶⁰ to R⁶¹ optionally form a ring with each other via one or more divalent linking groups; adjacent two or more of R⁶⁴ to R⁶⁵ optionally form a ring with each other via one or more divalent linking groups; adjacent two or more of R⁶⁸ optionally form a ring with each other via one or more divalent linking groups; adjacent two or more of R⁷⁰ optionally form a ring with each other via one or more divalent linking groups; adjacent two or more of R⁷¹ optionally form a ring with each other via one or more divalent linking groups; adjacent two or more of R⁷³ optionally form a ring with each other via one or more divalent linking groups; adjacent two or more of R⁷⁴ optionally form a ring with each other via one or more divalent linking groups; adjacent two or more of R⁷⁵ optionally form a ring with each other via one or more divalent linking groups; adjacent two or more of R⁷⁶ to R⁷⁷ optionally form a ring with each other via one or more divalent linking groups; adjacent two or more of R⁷⁸ to R⁷⁹ optionally form a ring with each other via one or more divalent linking groups; adjacent two or more of R⁸⁰ to R⁸¹ optionally form a ring with each other via one or more divalent linking groups;
X⁻ is an organic anion,
n1, n2, and n6 to n9 are each independently an integer from 0 to 4,
n4 and n5 are each independently an integer from 0 to 2,
each l is an integer from 0 to 4;
each k is an integer from 0 to 30;
each p is an integer from 0 to 4;
each q is an integer from 0 to 5;
each r is an integer from 0 to 4;
M is a transition metal; and
X, Y, and Z each independently comprises an electron withdrawing group.

8. The composition of claim 1, wherein the non-polymeric electron acceptor compound comprises a compound represented by one of Formulae (27A) to (30A): 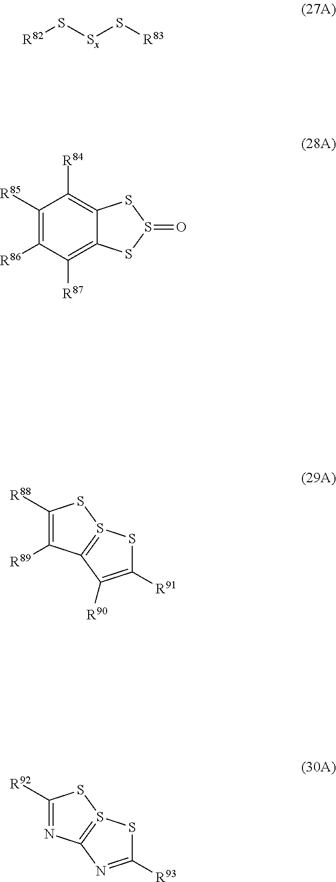
wherein, in Formulae (27A) to (30A),
R⁸² to R⁹³ are each independently hydrogen, deuterium, halogen, nitro, amino, cyano, pyridinium, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, or substituted or unsubstituted C₃₋₃₀ alkylheteroaryl;
each of R⁸² to R⁹³ optionally further comprises one or more divalent linking groups as a part of its structure;
R⁸² and R⁸³ optionally form a ring with each other via one or more divalent linking groups;
adjacent two or more of R⁸⁴ to R⁸⁷ optionally form a ring with each other via one or more divalent linking groups;
adjacent two or more of R⁸⁸ to R⁹¹ optionally form a ring with each other via one or more divalent linking groups; and
x is 1 or 2.

9. The composition of claim 1, comprising two or more of the non-polymeric electron acceptor compounds, wherein the two or more of the non-polymeric electron acceptor compounds have a greater electron affinity than the electron affinity of the photoacid generator compound.

10. The composition of claim 1, wherein the photoacid generator compound comprises an onium salt.

11. The composition of claim 1, wherein the photoacid generator compound comprises a nonionic compound or a zwitterionic compound.

12. The composition of claim 1, wherein the photoacid generator compound is a photoacid generating polymer.

13. A patterning forming method, comprising:
(a) applying a layer of the composition of claim 1 on a substrate;
(b) soft-baking the composition layer;
(c) exposing the soft-baked composition layer to EUV or electron beam activating radiation;
(d) post-exposure baking the composition layer; and
(e) developing the post-exposure baked composition layer to provide a resist relief image.

14. The method of claim 13, wherein the composition comprises two or more photoacid generator compounds, wherein the non-polymeric electron acceptor compound has a greater electron affinity than an electron affinity of each of the two or more photoacid generator compounds.

15. The method of claim 13, wherein the composition further comprises a base-labile material, a base soluble material, or a combination thereof.

16. The method of claim 13, wherein in the composition, the photoacid generator compound comprises a first anion and the non-polymeric electron acceptor compound comprises a second anion, wherein the first anion and the second anion are structurally the same.

17. The method of claim 13, wherein in the composition, the acid-sensitive polymer further comprises a second repeating unit, and wherein the second repeating unit comprises a hydroxyaryl group.
